(19) United States
(12) Patent Application Publication
(10) Pub. No.: US 2024/0347536 A1
(43) Pub. Date: Oct. 17, 2024

(54) INTEGRATED CIRCUIT AND METHOD FOR FORMING THE SAME

(71) Applicants: TAIWAN SEMICONDUCTOR MANUFACTURING COMPANY, LTD., Hsinchu (TW); NATIONAL TAIWAN UNIVERSITY, Taipei (TW)

(72) Inventors: Hsin-Cheng LIN, Taipei City (TW); Chun-Yi CHENG, New Taipei City (TW); Ching-Wang YAO, New Taipei City (TW); Chee-Wee LIU, Taipei City (TW)

(73) Assignees: TAIWAN SEMICONDUCTOR MANUFACTURING COMPANY, LTD., Hsinchu (TW); NATIONAL TAIWAN UNIVERSITY, Taipei (TW)

(21) Appl. No.: 18/299,663

(22) Filed: Apr. 12, 2023

(51) Int. Cl. H01L 27/092; H01L 21/02; H01L 21/8238; H01L 23/528; H01L 29/06; H01L 29/10; H01L 29/417; H01L 29/423; H01L 29/66; H01L 29/775

(52) U.S. Cl. CPC H01L 27/092; H01L 21/02532; H01L 21/823807; H01L 21/823814; H01L 21/823871; H01L 23/5286; H01L 29/0673; H01L 29/1033; H01L 29/41733; H01L 29/42392; H01L 29/66439; H01L 29/66545; H01L 29/775; H03F 3/213

(57) ABSTRACT

An integrated circuit includes a first transistor and a second transistor. The first transistor includes first semiconductor channel layers, first gate structure, and a first source structure and a first drain structure on opposites sides of the first gate structure. The second transistor includes second semiconductor channel layers, second gate structure, and a second source structure and a second drain structure on opposites sides of the second gate structure. The first source structure of the first transistor is electrically coupled to the second drain structure of the second transistor. A thickness of each of the first semiconductor channel layers is less than a thickness of each of the second semiconductor channel layers, and a bandgap of a material of the first semiconductor channel layers is larger than a bandgap of a material of the second semiconductor channel layers.

### BACKGROUND

The semiconductor integrated circuit (IC) industry has experienced rapid growth. Technological advances in IC materials and design have produced generations of ICs. Each generation has smaller and more complex circuits than the previous generation. However, these advances have increased the complexity of processing and manufacturing ICs. In the course of IC evolution, functional density (i.e., the number of interconnected devices per chip area) has generally increased while geometric size (i.e., the smallest component (or line) that can be created using a fabrication process) has decreased. This scaling-down process generally provides benefits by increasing production efficiency and lowering associated costs. However, since feature sizes continue to decrease, fabrication processes continue to become more difficult to perform. Therefore, it is a challenge to form reliable semiconductor devices at smaller and smaller sizes.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 is circuit diagram of an integrated circuit in accordance with some embodiments of the present disclosure.

FIG. 2A is a top view of an integrated circuit in accordance with some embodiments of the present disclosure.

FIGS. 2B to 2E are cross-sectional views of an integrated circuit in accordance with some embodiments of the present disclosure.

FIG. 3 is an exemplary experiment result in accordance with some embodiments of the present disclosure.

FIGS. 4A to 22E illustrate a method in various stages of forming an integrated circuit in accordance with some embodiments of the present disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

The gate all around (GAA) transistor structures may be patterned by any suitable method. For example, the structures may be patterned using one or more photolithography processes, including double-patterning or multi-patterning processes. Generally, double-patterning or multi-patterning processes combine photolithography and self-aligned processes, allowing patterns to be created that have, for example, pitches smaller than what is otherwise obtainable using a single, direct photolithography process. For example, in one embodiment, a sacrificial layer is formed over a substrate and patterned using a photolithography process. Spacers are formed alongside the patterned sacrificial layer using a self-aligned process. The sacrificial layer is then removed, and the remaining spacers may then be used to pattern the GAA structure.

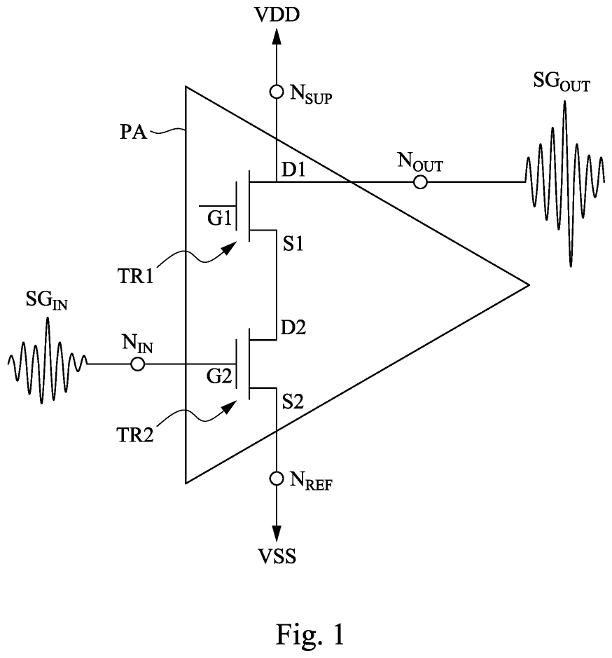

FIG. 1 is circuit diagram of an integrated circuit in accordance with some embodiments of the present disclosure. The integrated circuit of FIG. 1 may be a power amplifier PA. The power amplifier PA includes an input terminal N_{IN}, an output terminal N_{OUT}, a power supply terminal N_{SUP}, and a reference voltage terminal N_{REF}. The power amplifier PA may include a first transistor TR1 and a second transistor TR2. It is noted that, although not shown in FIG. 1, other elements such as capacitors, resistors, etc., may also be employed in the power amplifier PA. The first transistor TR1 includes a gate G1, a source S1, and a drain D1. Similarly, the second transistor TR2 includes a gate G2, a source S2, and a drain D2. In some embodiments, the source S1 of the first transistor TR1 is electrically coupled to the drain D2 of the second transistor TR2. The drain D1 of the first transistor TR1 is electrically coupled to a supply voltage VDD through the power supply terminal N_{SUP}. The source S2 of the second transistor TR2 is electrically coupled to a reference voltage VSS through the reference voltage terminal N_{REF}. In some embodiments, the reference voltage VSS may be a ground voltage, and thus the source S2 of the second transistor TR2 is grounded through the reference voltage terminal N_{REF}. In some embodiments, the gate G2 of the second transistor TR2 is configured to receive an input signal SG_{IN} through the input terminal N_{IN}, and the power amplifier PA is configured to convey an output signal SG_{OUT} through the output terminal N_{OUT} electrically coupled to the drain D1 of the first transistor TR1. In some embodiments, the gain of the power amplifier PA can be adjusted through the supply voltage VDD. In some embodiments, the first transistor TR1 and the second transistor TR2 are both N-type transistors, while the present disclosure is not limited thereto.

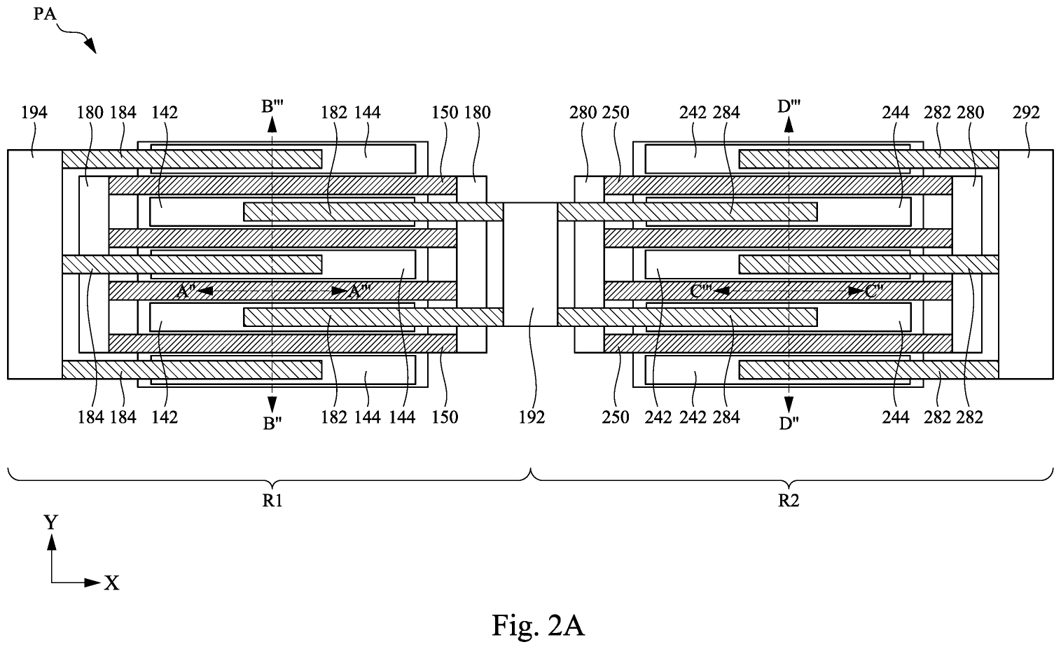

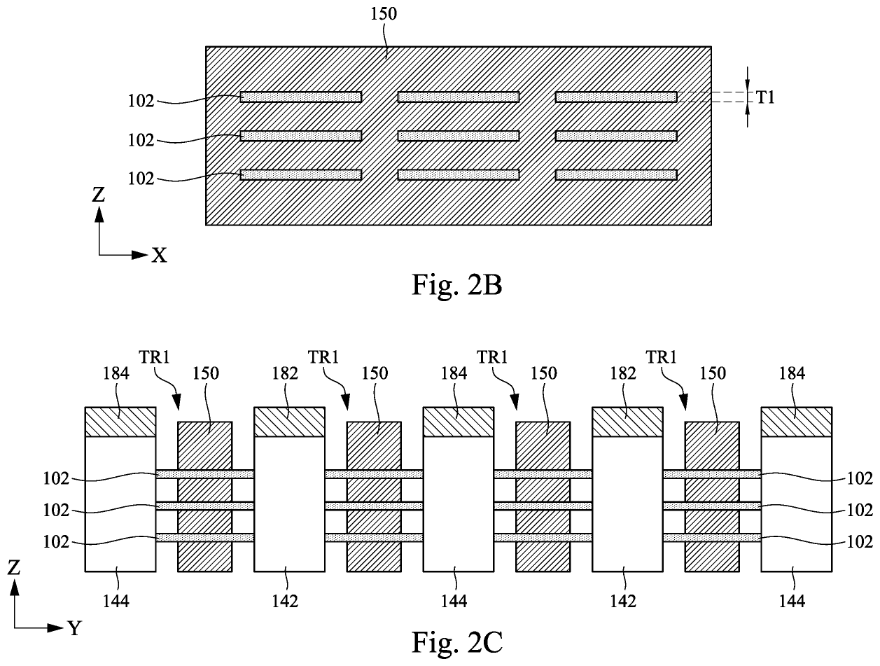

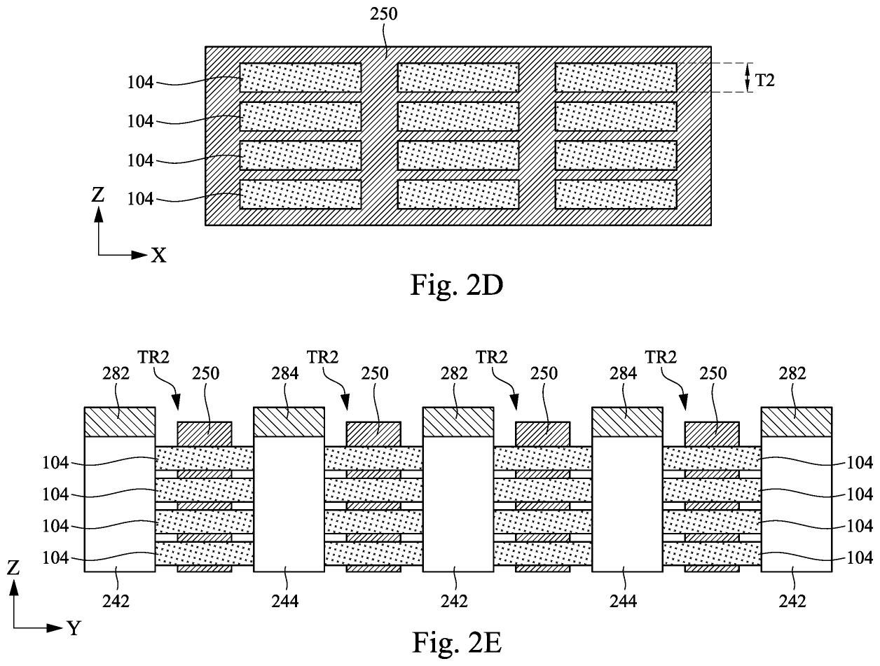

FIG. 2A is a top view of an integrated circuit in accordance with some embodiments of the present disclosure. FIGS. 2B to 2E are cross-sectional views of an integrated circuit in accordance with some embodiments of the present disclosure, in which FIGS. 2B to 2E are cross-sectional views along lines A″-A′″, B″-B′″, C″-C′″, and D″-D′″ of FIG. 2A. FIGS. 2A to 2E illustrate possible embodiments of the power amplifier PA of FIG. 1. It is noted that some elements of FIGS. 2A to 2E are similar to those described with respect to FIG. 1, such elements are labeled the same and relevant details will not be repeated for brevity.

FIG. 2A includes a first region R1 and a second region R2. An array of first transistors TR1 (see FIG. 2C) is disposed within the first region R1, and an array of second transistors TR2 (see FIG. 2E) is disposed within the second region R2, respectively. The numbers of the first transistors TR1 and the second transistors TR2 are merely used to explain, while more or less first transistors TR1 (and second transistors TR2) may also be employed.

Although several first transistors TR1 are illustrated, gates of the first transistors TR1 may be electrically coupled with each other, sources of the first transistors TR1 may be electrically coupled with each other, and drains of the first transistors TR1 may be electrically coupled with each other. Similarly, although several second transistors TR2 are illustrated, gates of the second transistors TR2 may be electrically coupled with each other, sources of the second transistors TR2 may be electrically coupled with each other, and drains of the second transistors TR2 may be electrically coupled with each other. Accordingly, the equivalent circuit of the structure shown in FIGS. 2A to 2E may be the same as the circuit shown in FIG. 1.

As shown in FIGS. 2B and 2C, with respect to the first transistors TR1, each of the first transistors TR1 may include a gate-all-around (GAA) configuration. For example, each of the first transistors TR1 may include semiconductor channel layers 102 vertically stacked one above another. In FIG. 2B, each of the first transistors TR1 may include several stacks of the semiconductor channel layers 102. For example, in the embodiments of FIG. 2B, several stacks (e.g., 3 stacks) of the semiconductor channel layers 102 are laterally arranged along the X-direction, in which each stack may include several semiconductor channel layers 102 (e.g., 3 layers) vertically stacked one above another along the Z-direction. In some embodiments, about 1-500 stacks of the semiconductor channel layers 102 may be laterally arranged along the X-direction. In some embodiments, each stack of the semiconductor channel layers 102 may include about 1-100 semiconductor channel layers 102. In some embodiments, the semiconductor channel layers 102 may include semiconductor material, such as Si, Ge, Sn, Si₁₋ₓGeₓ, Ge_{1-y}Sn_{y}, Si_{1-x-y}GeₓSn_{y}, III-V, etc.

Each of the first transistors TR1 may include a gate structure 150 wrapping around each of the semiconductor channel layers 102. For example, the gate structure 150 may be in contact with at least four surfaces of each semiconductor channel layer 102 (see FIG. 2B). In some embodiments, the gate structure 150 may include an interfacial layer, a gate dielectric layer over the interfacial layer, a work function metal layer over the gate dielectric layer, and a gate fill metal over the work function metal layer, which will be discussed later.

In FIG. 2C, each of the first transistors TR1 may include a source epitaxy structure 142 and a drain epitaxy structure 144 on opposite sides of the semiconductor channel layers 102, and on opposite sides of the gate structure 150. In some embodiments, the source epitaxy structure 142 and the drain epitaxy structure 144 may be made of suitable epitaxial material including Si, SiGe, Ge, III-V materials, or the like. In some embodiments where the first transistors TR1 are N-type transistors, the source epitaxy structure 142 and the drain epitaxy structure 144 may be doped with N-type dopants, such as phosphorus (P), arsenic (As), or antimony (Sb), or the like.

In FIG. 2A, gate contacts 180 are disposed over and electrically coupled to the gate structures 150 of the first transistors TR1. Source contacts 182 are disposed over and electrically coupled to the respective source epitaxy structures 142 of the first transistors TR1. Drain contacts 184 are disposed over and electrically coupled to the respective drain epitaxy structures 144 of the first transistors TR1. Conductive pad 192 is disposed over and electrically coupled to the source contacts 182. Conductive pad 194 is disposed over and electrically coupled to the drain contacts 184. In some embodiments, the conductive pad 194 may serve as the power supply terminal N_{SUP} and/or the output supply terminal N_{OUT} as described in FIG. 1.

With respect to the second transistors TR2, each of the second transistors TR2 may include a gate-all-around (GAA) configuration. For example, each of the second transistors TR2 may include semiconductor channel layers 104 vertically stacked one above another. In FIG. 2D, each of the second transistors TR2 may include several stacks of the semiconductor channel layers 104. For example, in the embodiments of FIG. 2D, several stacks (e.g., 3 stacks) of the semiconductor channel layers 104 are laterally arranged along the X-direction, in which each stack may include several semiconductor channel layers 104 (e.g., 4 layers) vertically stacked one above another along the Z-direction. In some embodiments, about 1-500 stacks of the semiconductor channel layers 104 may be laterally arranged the X-direction. In some embodiments, each stack of the semiconductor channel layers 104 may include about 1-500 semiconductor channel layers 104. In some embodiments, the semiconductor channel layers 104 may include semiconductor material, such as Si, Ge, Sn, Si₁₋ₓGeₓ, Ge_{1-y}Sn_{y}, Si_{1-x-y}GeₓSn_{y}, III-V, etc. In some embodiments, a material of the semiconductor channel layers 102 may be different from a material of the semiconductor channel layers 104.

Each of the second transistors TR2 may include a gate structure 250 wrapping around each of the semiconductor channel layers 104. For example, the gate structure 250 may be in contact with at least four surfaces of each semiconductor channel layer 104 (see FIG. 2D). In some embodiments, the gate structure 250 may include an interfacial layer, a gate dielectric layer over the interfacial layer, a work function metal layer over the gate dielectric layer, and a gate fill metal over the work function metal layer, which will be discussed later.

In FIG. 2E, each of the second transistors TR2 may include a source epitaxy structure 242 and a drain epitaxy structure 244 on opposite sides of the semiconductor channel layers 104, and on opposite sides of the gate structure 250. In some embodiments, the source epitaxy structure 242 and the drain epitaxy structure 244 may be made of suitable epitaxial material including Si, SiGe, Ge, III-V materials, or the like. In some embodiments where the second transistors TR2 are N-type transistors, the source epitaxy structure 242 and the drain epitaxy structure 244 may be doped with N-type dopants, such as phosphorus (P), arsenic (As), or antimony (Sb), or the like.

In FIG. 2A, gate contacts 280 are disposed over and electrically coupled to the gate structures 250 of the second transistors TR2. Source contacts 282 are disposed over and electrically coupled to the respective source epitaxy structures 242 of the second transistors TR2. Drain contacts 284 are disposed over and electrically coupled to the respective drain epitaxy structures 244 of the second transistors TR2. Conductive pad 292 is disposed over and electrically coupled to the source contacts 282. Conductive pad 192 is disposed over and electrically coupled to the drain contacts 284. In some embodiments, the gate contacts 280 may serve as the input signal terminal N_{IN} as described in FIG. 1. In some embodiments, the conductive pad 292 may serve as the reference voltage terminal N_{REF} as described in FIG. 1.

The conductive pad 192 electrically connects the source contacts 182 to the drain contacts 284, and thus the sources of the first transistors TR1 (e.g., source epitaxy structures 142) are electrically coupled to the drains of the second transistors TR2 (e.g., drain epitaxy structures 244). Moreover, the conductive pad 194 is electrically coupled to the supply voltage VDD, and thus the drains of the first transistors TR1 (e.g., drain epitaxy structures 144) are electrically coupled to the supply voltage VDD. Furthermore, the conductive pad 292 is electrically coupled to the reference voltage VSS, and thus the sources of the second transistors TR2 (e.g., source epitaxy structures 242) are electrically coupled to the reference voltage VSS.

With respect to FIGS. 2B to 2E, the semiconductor channel layers 102 of the first transistor TR1 may include a different material and a different thickness than the semiconductor channel layers 104 of the second transistor TR2. In some embodiments, the thickness T1 of the semiconductor channel layer 102 is less than the thickness T2 of the semiconductor channel layer 104. In some embodiments, the thickness T1 of the semiconductor channel layer 102 is in a range from about 0.5 nm to about 5 nm. In some embodiments, the thickness T2 of the semiconductor channel layer 104 is in a range from about 5 nm to about 50 nm. In other embodiments, the thickness T2 of the semiconductor channel layer 104 is in a range from about 2 nm to about 50 nm. In some embodiments, the thickness T1 of the semiconductor channel layer 102 may be less than about 5 nm, while the thickness T2 of the semiconductor channel layer 104 is greater than about 5 nm. In some embodiments, the semiconductor channel layers 102 are offset from the semiconductor channel layers 104 along the vertical direction (e.g., Z-direction). In some embodiments, the number of the semiconductor channel layers 102 of the first transistor TR1 may be less than the number of the semiconductor channel layers 104 of the second transistor TR2, while the present disclosure is not limited thereto. In other embodiments, the number of the semiconductor channel layers 102 of the first transistor TR1 may be equal to or larger than the number of the semiconductor channel layers 104 of the second transistor TR2.

The thickness T1 of the semiconductor channel layer 102 is very thin, and thus the semiconductor channel layer 102 can also be referred to as ultrathin body (UTB) or ultrathin body channel layer. In some embodiments, if the thickness T1 of the semiconductor channel layer 102 is sufficiently thin, quantum confinement would occur.

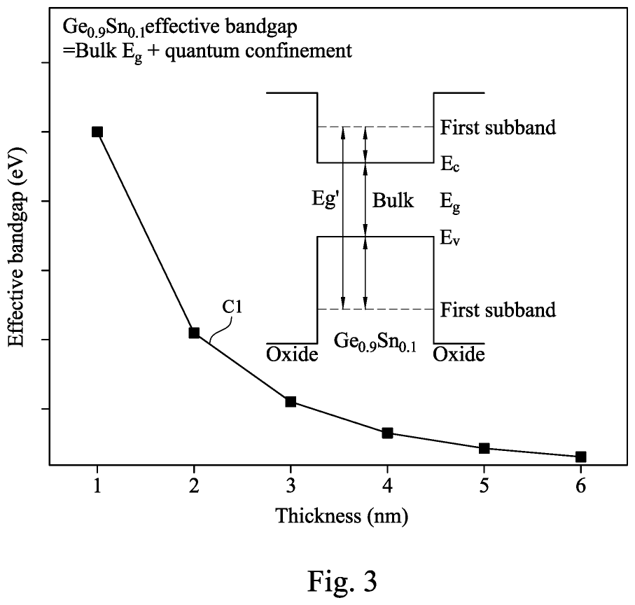

FIG. 3 is an exemplary experiment result in accordance with some embodiments of the present disclosure, where a Ge_{0.9}Sn_{0.1} is taken as an example. In a bulk Ge_{0.9}Sn_{0.1}, the Ge_{0.9}Sn_{0.1} has a bandgap E_{g}, which is the energy gap between the conduction band energy E_{c} and the valance band energy Eᵥ. In the bulk Ge_{0.9}Sn_{0.1}, carriers are allowed to move in three dimensions. When thickness of the Ge_{0.9}Sn_{0.1} layer decreases, the carriers may be confined and are forced to move in only two dimensions. Such condition may be referred to as “quantum confinement”, and the bulk Ge_{0.9}Sn_{0.1} layer becomes a Ge_{0.9}Sn_{0.1} quantum well. In a Ge_{0.9}Sn_{0.1} quantum well, carriers can only have discrete energy levels called “energy subbands.” In the Ge_{0.9}Sn_{0.1} quantum well, the effective bandgap E_{g}′ of the Ge_{0.9}Sn_{0.1} quantum well may be the energy gap between the first subband at conduction band and the first subband at valance band. Accordingly, the effective bandgap E_{g}′ of the Ge_{0.9}Sn_{0.1} quantum well may be larger than the bandgap E_{g} of the bulk Ge_{0.9}Sn_{0.1}. Curve Cl of FIG. 3 also shows that when the thickness of the Ge_{0.9}Sn_{0.1} layer is less than 5 nm, larger effective bandgap E_{g}′ can be achieved due to quantum confinement.

Referring back to FIGS. 2B to 2E, as mentioned above, the thickness T1 of the semiconductor channel layer 102 is controlled such that quantum confinement occurs. Accordingly, the semiconductor channel layer 102 can also be referred to as a quantum well or quantum well channel layer. However, the thickness T2 of the semiconductor channel layer 104 may be thick enough and there is no quantum confinement occurs in the semiconductor channel layer 104, and thus the semiconductor channel layer 104 may be a bulk material rather than a quantum well. Due to quantum confinement effect, the effective bandgap of nanoscale material of the semiconductor channel layer 102 may be greater than the bandgap of the semiconductor channel layer 104. The larger bandgap of the semiconductor channel layer 102 will increase the breakdown voltage (V_{BD}) of the first transistor TR1. The larger breakdown voltage may allow the first transistor TR1 to sustain even larger supply voltage VDD and will further enlarge the output power of the power amplifier PA. On the other hand, the thicker semiconductor channel layer 104 will ensure that the second transistor TR2 has larger on current ION, which is beneficial for providing high gain through the power amplifier PA. In some embodiments, the semiconductor channel layer 104 may also include nanoscale material, while no quantum confinement effect occurs in the semiconductor channel layer 104.

In some embodiments, the semiconductor channel layers 102 and 104 may be made of silicon germanium but with different compositions. For example, the semiconductor channel layers 102 may be made of Si_{0.7}Ge_{0.3}, while the semiconductor channel layers 104 may be made of Si_{0.3}Ge_{0.7}. In some embodiments, the semiconductor channel layer 102 can be referred to as silicon germanium quantum well, and the semiconductor channel layer 104 can be referred to as bulk silicon germanium. In some embodiments, the silicon concentration of the semiconductor channel layers 102 is greater than the silicon concentration of the semiconductor channel layers 104, while the limitation is not limited thereto. In other embodiments, the semiconductor channel layers 102 and 104 may be made of Si, Ge, Sn, Si₁₋ₓGeₓ, Ge_{1-y}Sn_{y}, Si_{1-x-y}GeₓSn_{y}, III-V, etc.

As shown in the cross-sectional view of FIGS. 2B and 2D, each of the semiconductor channel layers 102 and 104 may include a rectangular cross-section, while the present disclosure is not limited thereto. For example, cross-sections of the semiconductor channel layers 102 and 104 may be rectangular, square, diamond, etc., with or without rounded corners. In other embodiments, cross-sections of the semiconductor channel layers 102 and 104 may be circular, elliptical, etc. In some embodiments where the semiconductor channel layers 102 and 104 have circular cross-section, a diameter of each semiconductor channel layer 102 is in a range from about 0.5 to about 7 nm, and a diameter of each semiconductor channel layer 104 is in a range from about 7 to about 50 nm.

In some embodiments, the semiconductor channel layers 102 may include different thicknesses. For example, at least one of the semiconductor channel layers 102 may include a different thickness than another one of the semiconductor channel layers 102. Similarly, the semiconductor channel layers 104 may include different thicknesses. For example, at least one of the semiconductor channel layers 104 may include a different thickness than another one of the semiconductor channel layers 104.

In some embodiments, vertical distances between two adjacent semiconductor channel layers 102 may be different. For example, a vertical distance between two adjacent semiconductor channel layers 102 may be different from a vertical distance between other two adjacent semiconductor channel layers 102. Similarly, vertical distances between two adjacent semiconductor channel layers 104 may be different. For example, a vertical distance between two adjacent semiconductor channel layers 104 may be different from a vertical distance between other two adjacent semiconductor channel layers 104. In some embodiments, the vertical distance is in a range from about 3 nm to about 100 nm.

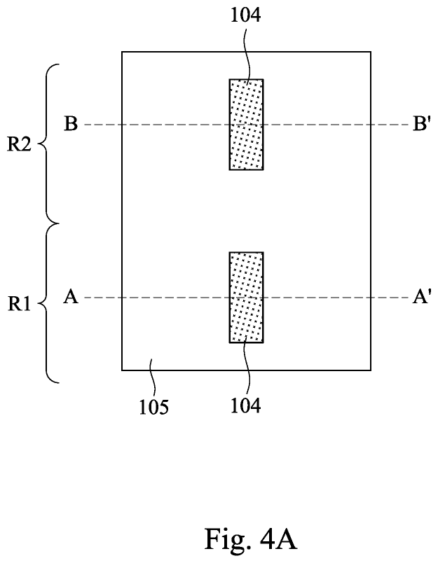

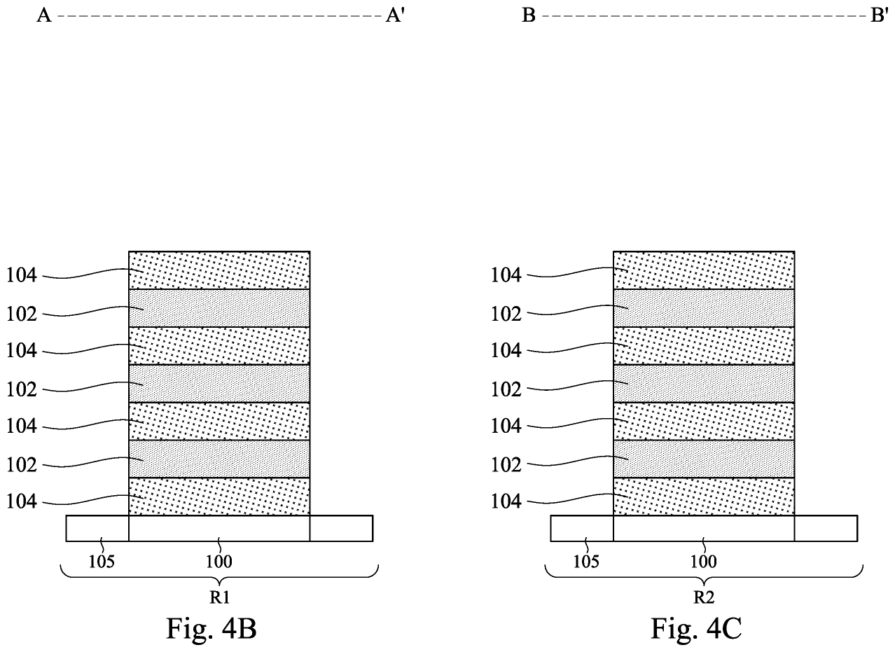

FIGS. 4A to 22E illustrate a method in various stages of forming an integrated circuit in accordance with some embodiments of the present disclosure. Although FIGS. 4A to 22E are described as a series of acts, it will be appreciated that these acts are not limiting in that the order of the acts can be altered in other embodiments, and the methods disclosed are also applicable to other structures. In other embodiments, some acts that are illustrated and/or described may be omitted in whole or in part. FIGS. 4A to 22E provide possible method for forming the power amplifier PA as discussed in FIGS. 1 to 2E. It is noted that some elements of FIGS. 4A to 22E may be similar to those described with respect to FIGS. 1 to 2E, and thus relevant details will not be repeated for brevity.

Reference is made to FIGS. 4A, 4B, and 4C, in which FIG. 4A is a top view, and FIGS. 4B and 4C are cross-sectional views along lines A-A′ and B-B′ of FIG. 4A, respectively. In the top view of FIG. 4A, shown there are a first region R1 and a second region R2 of a substrate (not shown), in which a first transistor TR1 and a second transistor TR2 are going to be formed over the first region R1 and the second region R2 of the substrate, respectively, and will be discussed throughout the following processes. In some embodiments, the substrate may be a silicon substrate. A buffer layer 100 is disposed over the substrate. In some embodiments, the buffer layer 100 may be made of a semiconductor material, such as germanium (Ge).

Two stacks of alternating semiconductor layers 102 and semiconductor layers 104 are formed over the buffer layer 100 (or the substrate), in which a first stack of the alternating semiconductor layers 102 and semiconductor layers 104 is formed within the first region R1 and a second stack of the alternating semiconductor layers 102 and semiconductor layers 104 is formed within the second region R2, respectively. In some embodiments, the semiconductor channel layers 102 and 104 may be made of silicon germanium but with different compositions. For example, the semiconductor channel layers 102 may be made of Si_{0.7}Ge_{0.3}, while the semiconductor channel layers 104 may be made of Si_{0.3}Ge_{0.7}. In other embodiments, the semiconductor channel layers 102 and 104 may be made of Si, Ge, Sn, Si₁₋ₓGeₓ, Ge_{1-y}Sn_{y}, Si_{1-x-y}GeₓSn_{y}, III-V, etc. In some embodiments, the semiconductor layers 102 and 104 can also be referred to as nanosheets, nanowires, nanostructures, or the like. In some embodiments, as mentioned above with respect to FIGS. 2A to 2E, and FIG. 3, the thicknesses of the semiconductor layers 102 and the semiconductor layers 104 are controlled such that quantum confinement may occur in the semiconductor layers 102, while no quantum confinement occurs in the semiconductor layers 104. In some embodiments, each stack may include four semiconductor layers 104 and three semiconductor layers 102, while the present disclosure is not limited thereto. In some embodiments, the bottommost semiconductor layers 104 are in contact with the buffer layer 100.

An isolation structure 105 is formed laterally surrounding the buffer layer 100. In some embodiments, the isolation structure 105 may be shallow trench isolation (STI) structure or other suitable isolation structure. In some embodiments, the isolation structure 105 may be made of oxide (e.g., silicon oxide), nitride (e.g., silicon nitride), or combinations thereof.

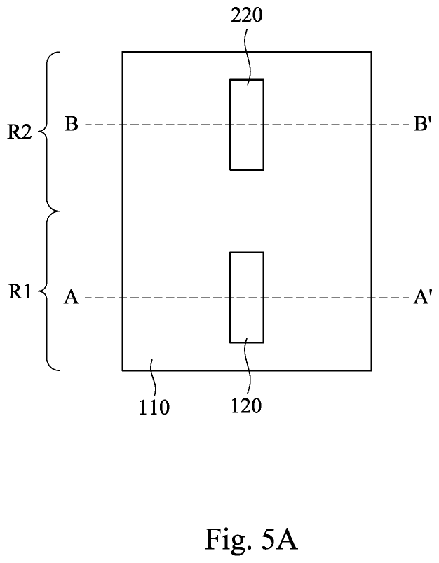

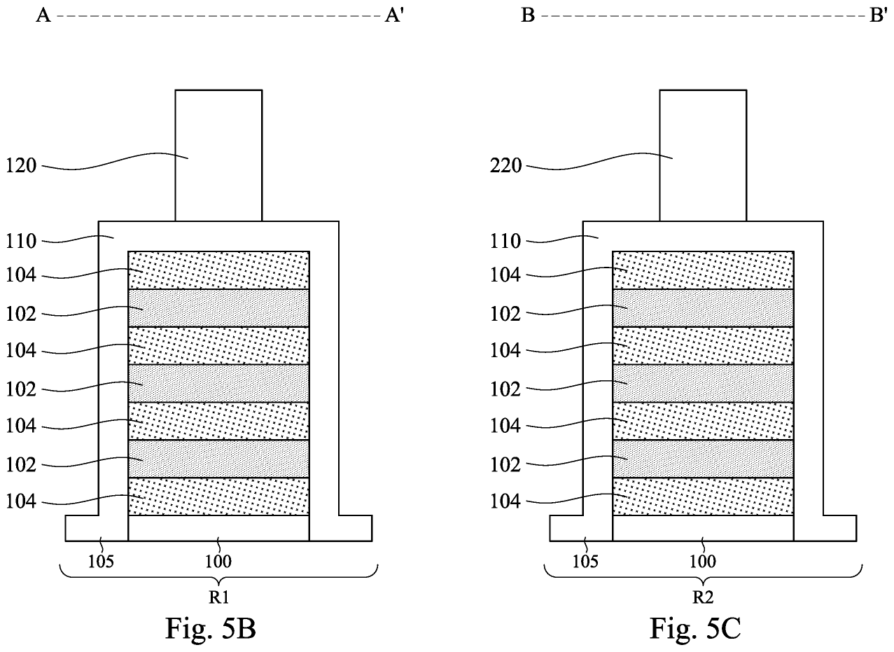

Reference is made to FIGS. 5A, 5B, and 5C, in which FIG. 5A is a top view, and FIGS. 5B and 5C are cross-sectional views along lines A-A′ and B-B′ of FIG. 5A, respectively. A sacrificial dielectric layer 110 is formed conformal to the stacks of the alternating semiconductor layers 102 and semiconductor layers 104. In some embodiments, the sacrificial dielectric layer 110 may be made of oxide, such as silicon oxide. In some embodiments, the sacrificial dielectric layer 110 may be formed by thermal oxidation or other suitable deposition processes.

Dummy gate structures 120 and 220 are formed over the stacks of the alternating semiconductor layers 102 and semiconductor layers 104, in which the dummy gate structures 120 and 220 are within the first regions R1 and the second region R2, respectively. In some embodiments, the dummy gate structures 120 and 220 may be made of amorphous silicon, polycrystalline-silicon (polysilicon), polycrystalline silicon-germanium (poly-SiGe), or the like. In some embodiments, the dummy gate structures 120 and 220 may be formed by, for example, depositing a dummy gate layer over the stacks of the alternating semiconductor layers 102 and semiconductor layers 104, and then patterning the dummy gate layer.

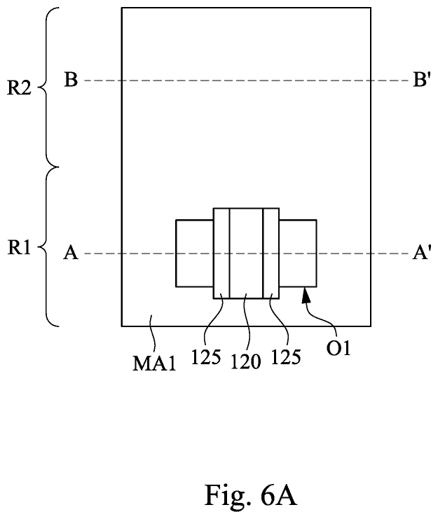

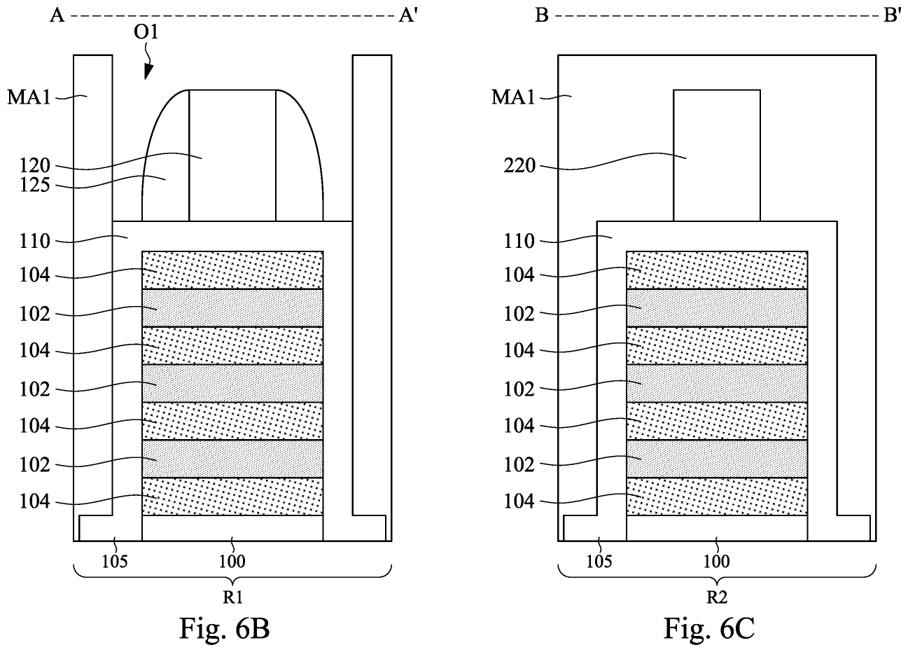

Reference is made to FIGS. 6A, 6B, and 6C, in which FIG. 6A is a top view, and FIGS. 6B and 6C are cross-sectional views along lines A-A′ and B-B′ of FIG. 6A, respectively. A patterned mask MA1 is formed covering the dummy gate structure 220, and the patterned mask MA1 may include an opening O1 exposing the dummy gate structure 120. In some embodiments, the patterned mask MA1 is made of photoresist, and may be formed by suitable photolithography process.

Gate spacers 125 are formed on opposite sidewalls of the dummy gate structure 120. In some embodiments, the gate spacers 125 may be formed by insulating dielectric material, such as a silicon nitride-based material. Examples of the silicon nitride-based material can be SiN, SION, SiOCN or SiCN and combinations thereof. In some embodiments, the gate spacers 125 may be formed by, for example, depositing a gate spacer layer blanket over the dummy gate structure 120, and then performing an etching process to remove horizontal portions of the gate spacer layer, while leaving vertical portions of the gate spacer layer on opposite sidewalls of the dummy gate structure 120.

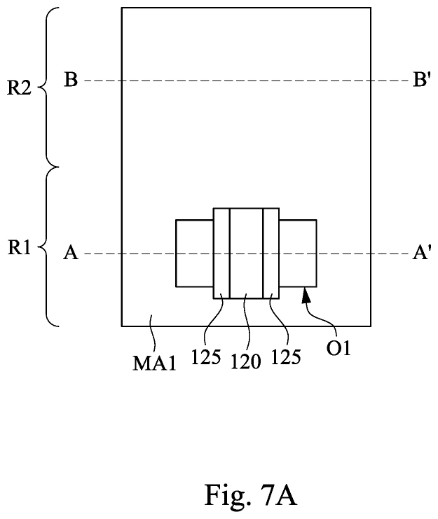

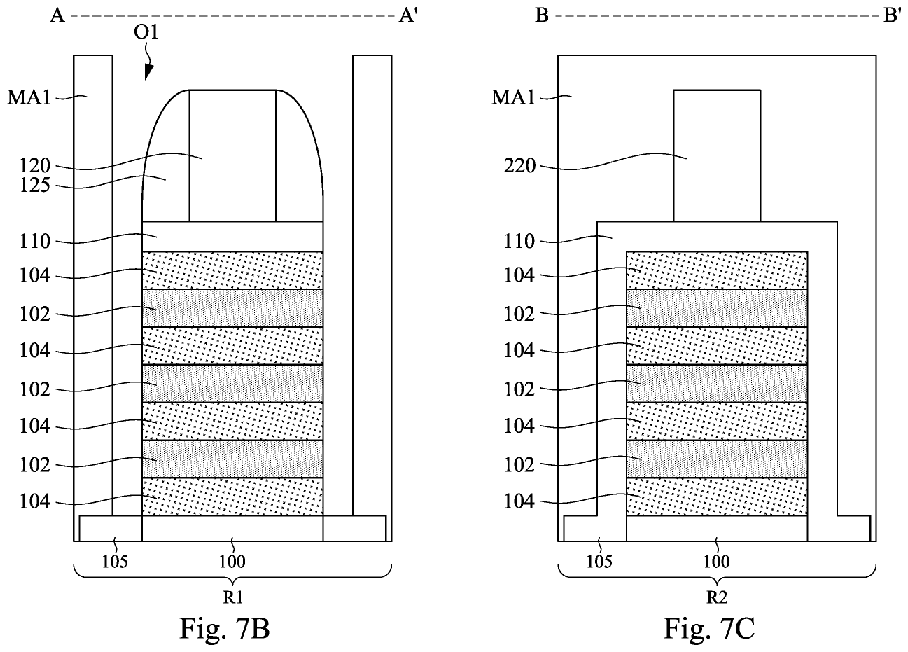

Reference is made to FIGS. 7A, 7B, and 7C, in which FIG. 7A is a top view, and FIGS. 7B and 7C are cross-sectional views along lines A-A′ and B-B′ of FIG. 7A, respectively. An etching process is performed, through the opening O1 of the patterned mask MA1, to remove exposed portions of the first stack of the alternating semiconductor layers 102 and semiconductor layers 104 within the first region R1 by using the patterned mask MA1, the dummy gate structure 120, and the gate spacers 125 as etch mask. In some embodiments, the etching process may be an anisotropic etch, such as dry etch.

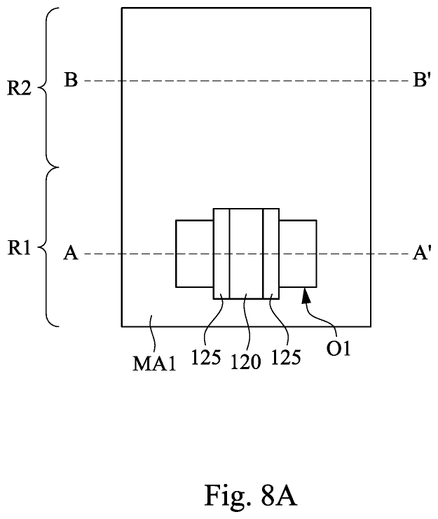

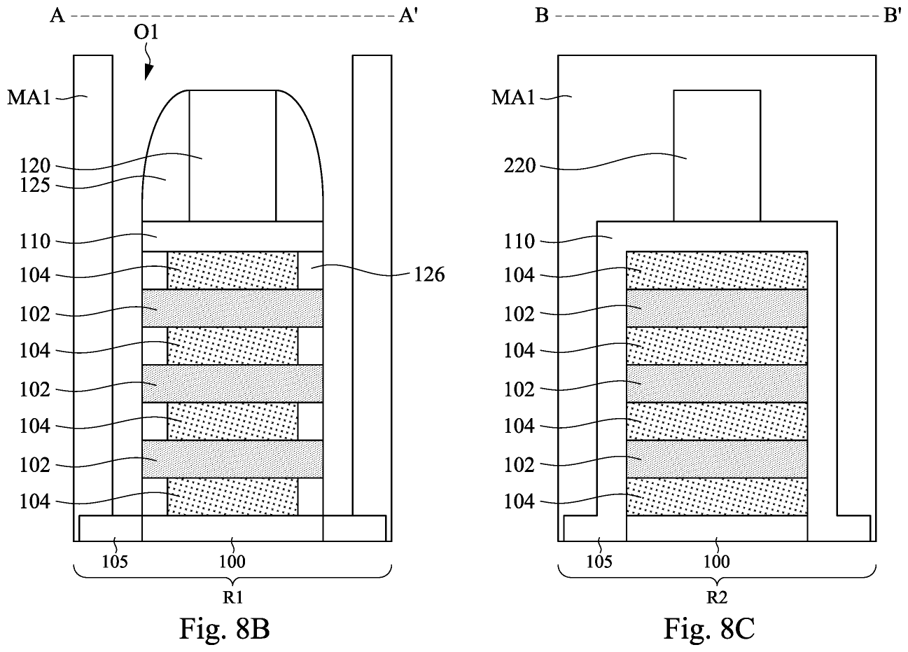

Reference is made to FIGS. 8A, 8B, and 8C, in which FIG. 8A is a top view, and FIGS. 8B and 8C are cross-sectional views along lines A-A′ and B-B′ of FIG. 8A, respectively. Portions of the semiconductor layers 104 exposed through the opening O1 of the patterned mask MA1 are laterally etched to form sidewall recesses, and then inner spacers 126 are formed in the sidewall recesses. The inner spacers 126 may be deposited by a conformal deposition process, such as CVD, ALD, or the like. The inner spacers 126 may be formed by, for example, depositing an inner spacer layer filling the sidewall recesses of the semiconductor layers 104, and then performing an anisotropic etching to remove portions of the inner spacer layer outside the sidewall recesses. In some embodiments, the inner spacers 126 may be formed by insulating dielectric material, such as a silicon nitride-based material. Examples of the silicon nitride-based material can be SiN, SiON, SiOCN or SiCN and combinations thereof.

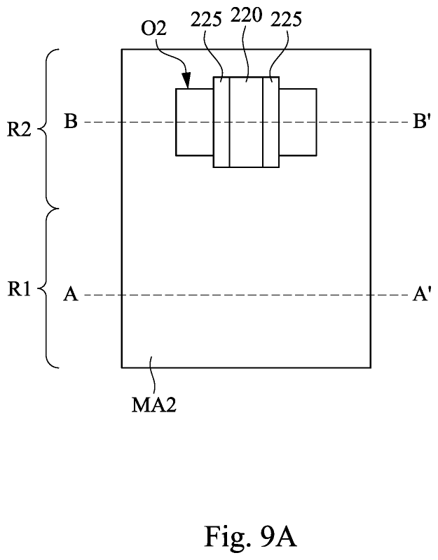

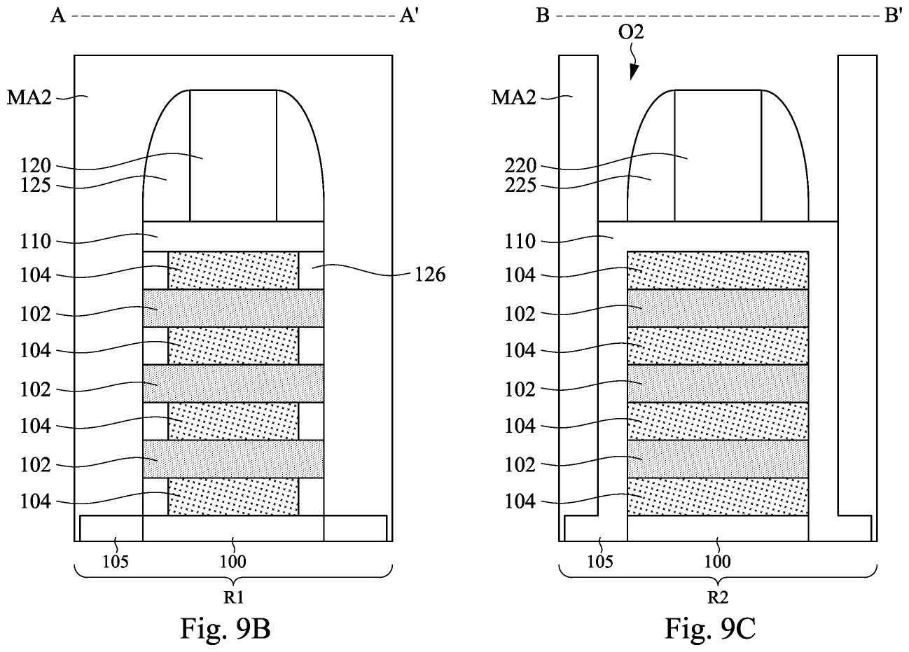

Reference is made to FIGS. 9A, 9B, and 9C, in which FIG. 9A is a top view, and FIGS. 9B and 9C are cross-sectional views along lines A-A′ and B-B′ of FIG. 9A, respectively. The patterned mask MA1 is removed. Then, a patterned mask MA2 is formed covering the dummy gate structure 120, and the patterned mask MA2 may include an opening O2 exposing the dummy gate structure 220. In some embodiments, the patterned mask MA2 is made of photoresist, and may be formed by suitable photolithography process.

Gate spacers 225 are formed on opposite sidewalls of the dummy gate structure 220. In some embodiments, the gate spacers 225 may be formed by insulating dielectric material, such as a silicon nitride-based material. Examples of the silicon nitride-based material can be SiN, SION, SiOCN or SiCN and combinations thereof. In some embodiments, the gate spacers 225 may be formed by, for example, depositing a gate spacer layer blanket over the dummy gate structure 220, and then performing an etching process to remove horizontal portions of the gate spacer layer, while leaving vertical portions of the gate spacer layer on opposite sidewalls of the dummy gate structure 220.

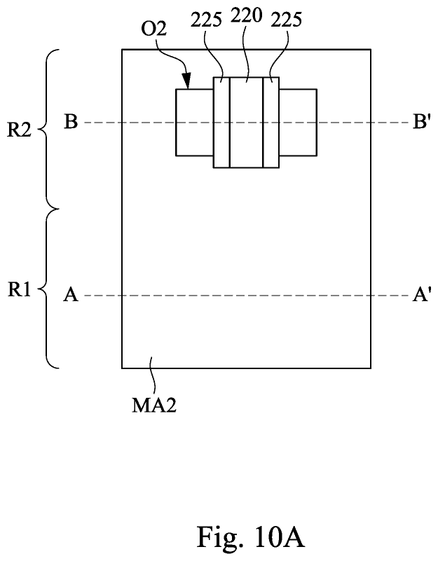

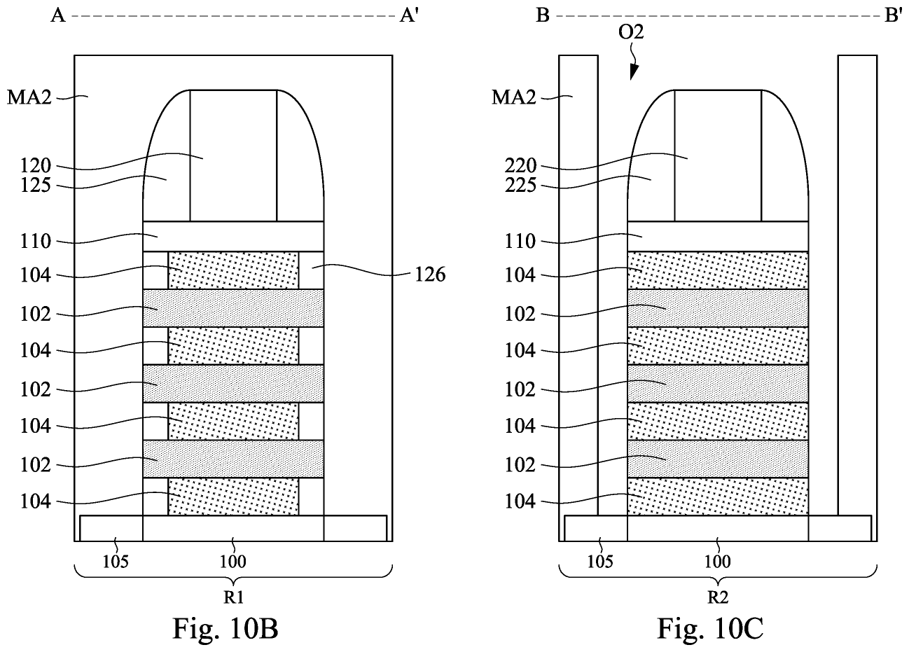

Reference is made to FIGS. 10A, 10B, and 10C, in which FIG. 10A is a top view, and FIGS. 10B and 10C are cross-sectional views along lines A-A′ and B-B′ of FIG. 10A, respectively. An etching process is performed, through the opening O2 of the patterned mask MA2, to remove exposed portions of the second stack of the alternating semiconductor layers 102 and semiconductor layers 104 within the second region R2 by using the patterned mask MA2, the dummy gate structure 220, and the gate spacers 225 as etch mask. In some embodiments, the etching process may be an anisotropic etch, such as dry etch.

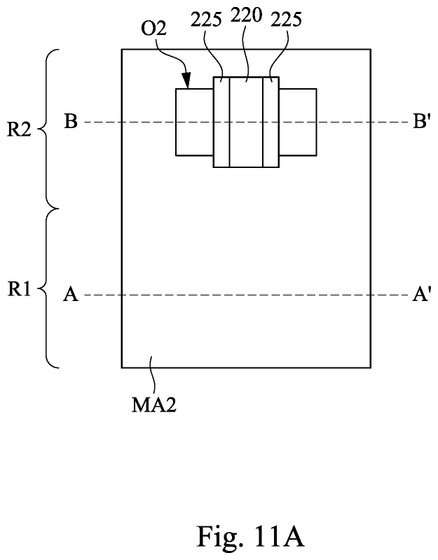

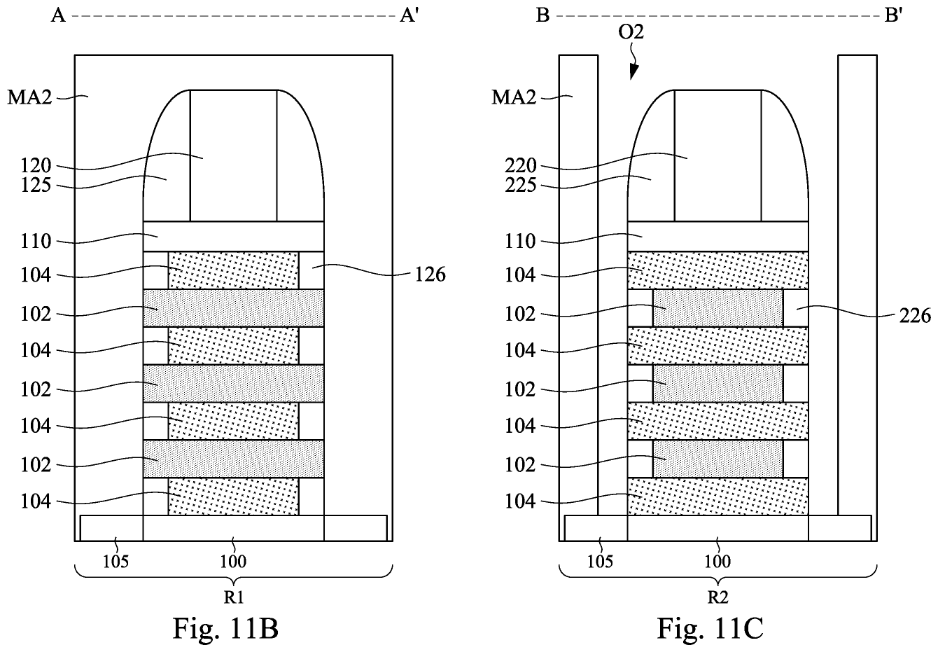

Reference is made to FIGS. 11A, 11B, and 11C, in which FIG. 11A is a top view, and FIGS. 11B and 11C are cross-sectional views along lines A-A′ and B-B′ of FIG. 11A, respectively. Portions of the semiconductor layers 102 exposed through the opening O2 of the patterned mask MA2 are laterally etched to form sidewall recesses, and then inner spacers 226 are formed in the sidewall recesses. The inner spacers 226 may be deposited by a conformal deposition process, such as CVD, ALD, or the like. The inner spacers 226 may be formed by, for example, depositing an inner spacer layer filling the sidewall recesses of the semiconductor layers 102, and then performing an anisotropic etching to remove portions of the inner spacer layer outside the sidewall recesses. In some embodiments, the inner spacers 226 may be formed by insulating dielectric material, such as a silicon nitride-based material. Examples of the silicon nitride-based material can be SiN, SION, SiOCN or SiCN and combinations thereof.

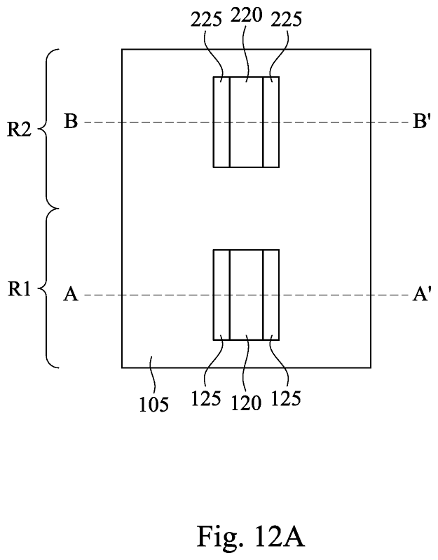

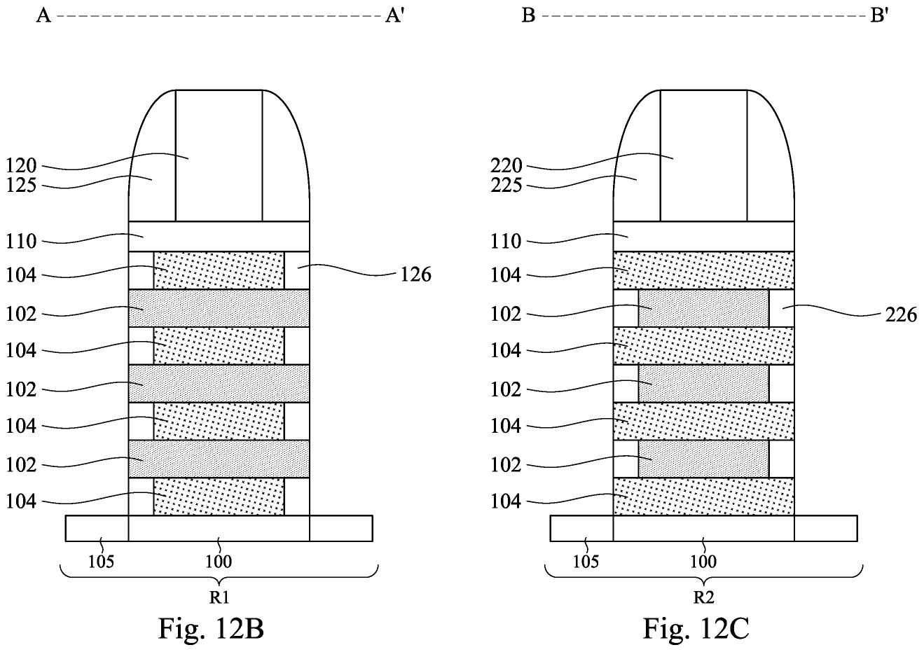

Reference is made to FIGS. 12A, 12B, and 12C, in which FIG. 12A is a top view, and FIGS. 12B and 12C are cross-sectional views along lines A-A′ and B-B′ of FIG. 12A, respectively. The patterned mask MA2 is removed. In some embodiments where the patterned mask MA2 is made of photoresist, the patterned mask MA2 may be removed by ashing or striping.

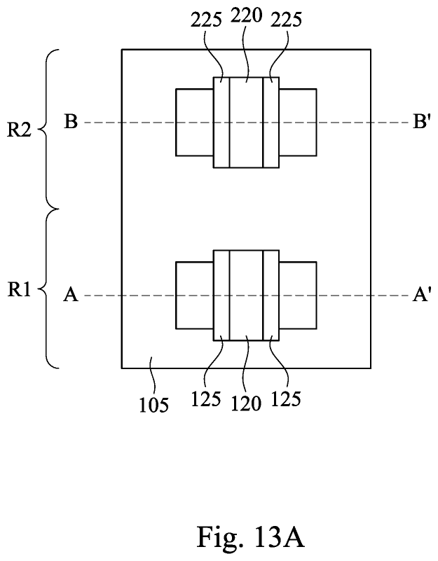

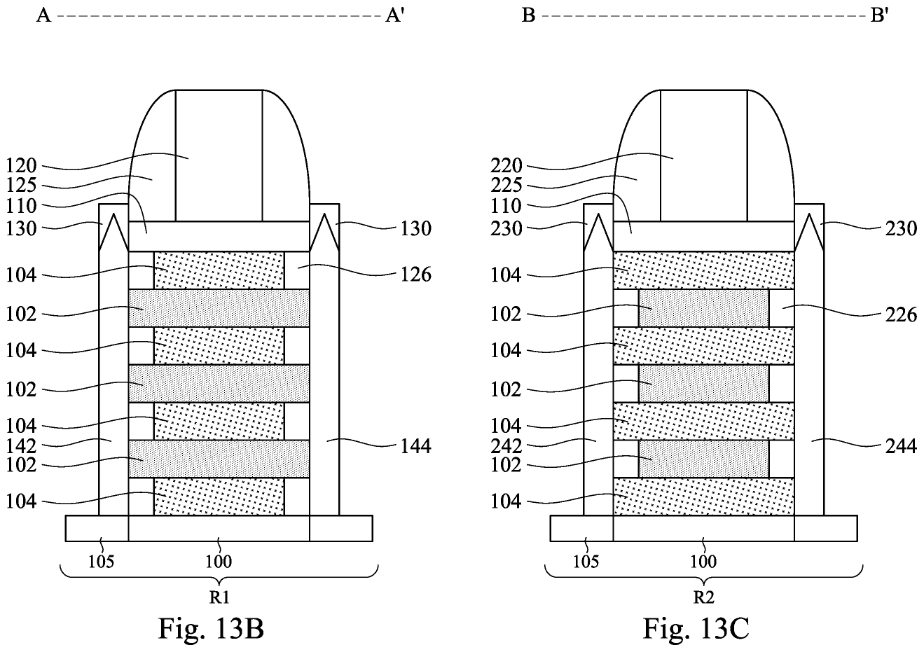

Reference is made to FIGS. 13A, 13B, and 13C, in which FIG. 13A is a top view, and FIGS. 13B and 13C are cross-sectional views along lines A-A′ and B-B′ of FIG. 13A, respectively. Source/drain epitaxy structures 142 and 144 are formed on opposite ends of the exposed semiconductor layers 102 within the first region R1, and source/drain epitaxy structures 242 and 244 are formed on opposite ends of the exposed semiconductor layers 104 within the second region R2. In some embodiments, the source/drain epitaxy structures 142, 144, 242 and 244 may be formed by epitaxial growth (SEG) process. In some embodiments, the source/drain epitaxy structures 142, 144, 242 and 244 may be made of suitable epitaxial material including Si, SiGe, Ge, III-V materials, or the like. In some embodiments, the source/drain epitaxy structures 142 and 144 may serve as the source region and the drain region as described in FIGS. 2A to 2E. Similarly, the source/drain epitaxy structures 242 and 244 may serve as the source region and the drain region as described in FIGS. 2A to 2E.

Source/drain contacts 130 are formed over the source/drain epitaxy structures 142 and 144, and source/drain contacts 230 are formed over the source/drain epitaxy structures 142 and 144, respectively. In some embodiments, the source/drain contacts 130 and 230 may be made of conductive material, such as metal. The conductive material may include one or more layers of Co, Ni, W, Ti, Ta, Cu, Al, TiN, and TaN, combinations thereof, and/or other suitable material.

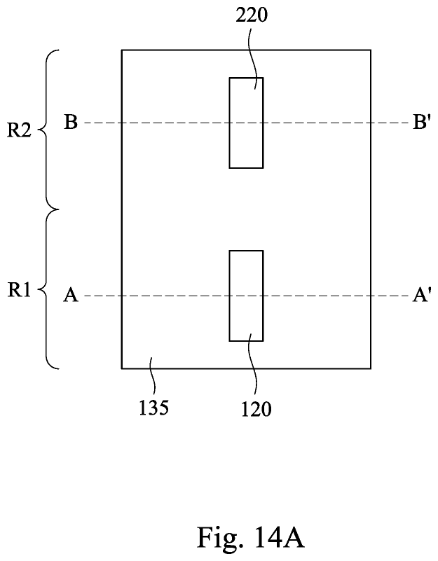

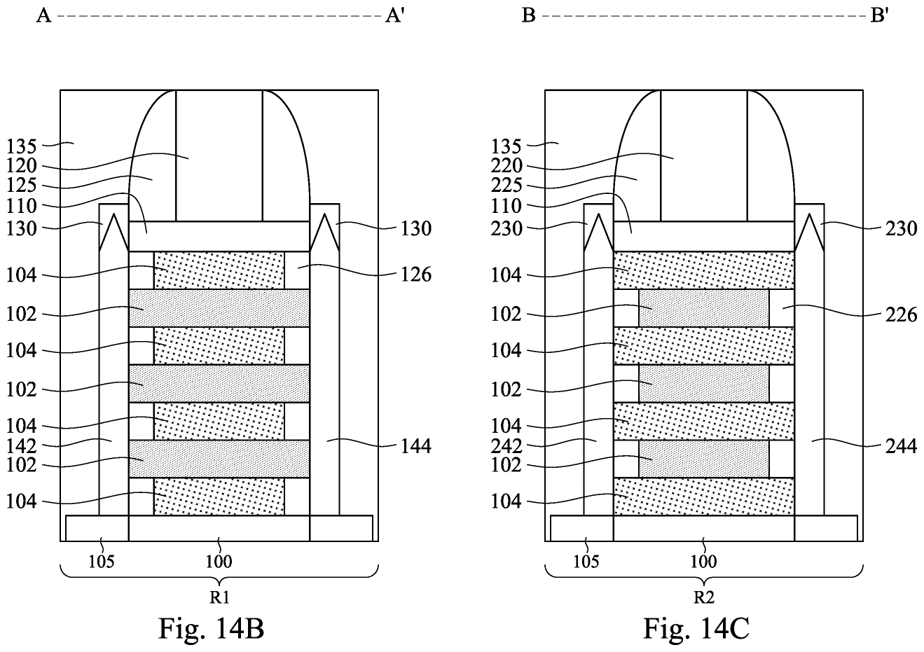

Reference is made to FIGS. 14A, 14B, and 14C, in which FIG. 14A is a top view, and FIGS. 14B and 14C are cross-sectional views along lines A-A′ and B-B′ of FIG. 14A, respectively. Isolation material 135 is formed covering the source/drain epitaxy structures 142, 144, 242, and 244, and the source/drain contacts 130 and 230. In some embodiments, the isolation material 135 may be made of suitable dielectric material, such as SiOC, or other suitable dielectric material. In some embodiments, the isolation material 135 may be formed by, for example, depositing a dielectric material blanket over the structure shown in FIGS. 13A to 13C, and then performing a planarization process to remove excess dielectric material until the dummy gate structures 120 and 220 are exposed. In some embodiments, the isolation material 135 can also be referred to as interlayer dielectric (ILD).

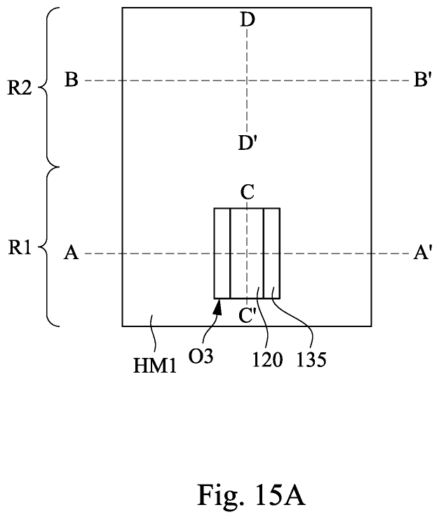

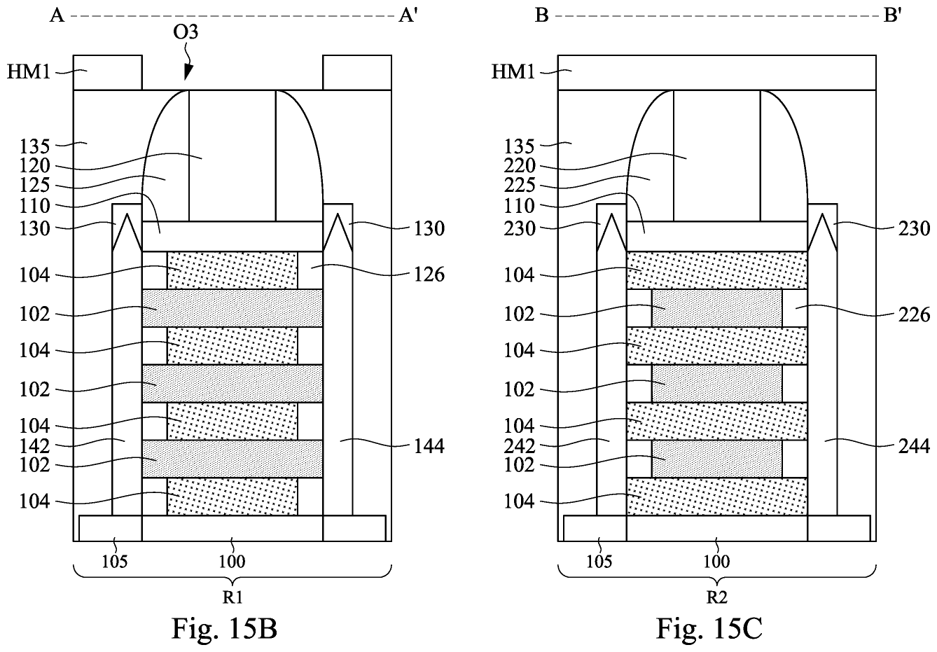

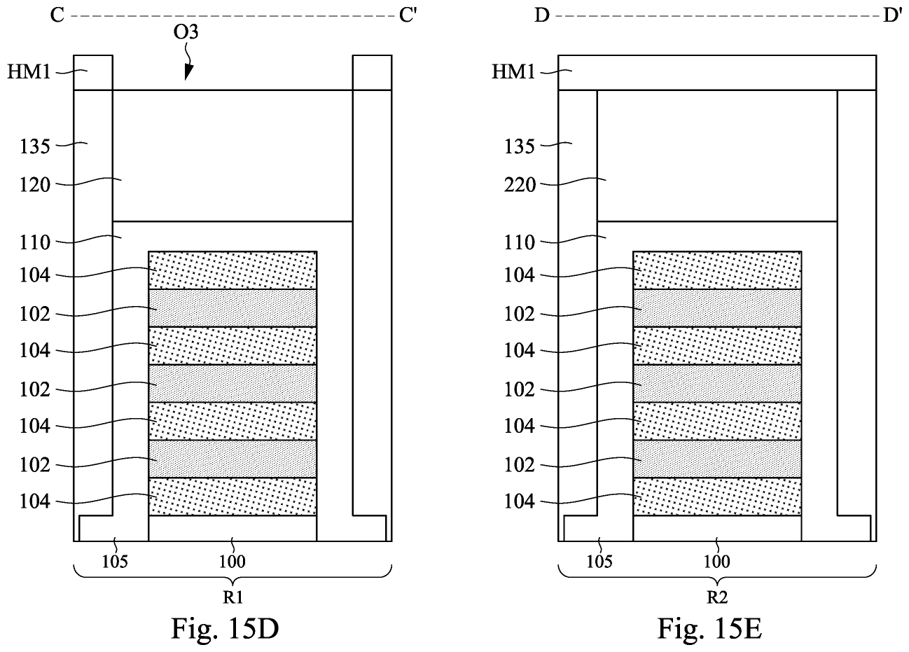

Reference is made to FIGS. 15A, 15B, 15C, 15D, and 15E in which FIG. 15A is a top view, and FIGS. 15B, 15C, 15D, and 15E are cross-sectional views along lines A-A′, B-B′, C-C′, and D-D′ of FIG. 15A, respectively. A patterned hard mask HM1 is formed over the isolation material 135 and covers the dummy gate structure 220, and the patterned hard mask HM1 may include an opening O3 exposing the dummy gate structure 120. In some embodiments, the patterned hard mask HM1 may be made of suitable dielectric material, such as SiON, or other suitable dielectric material. In some embodiments, the patterned hard mask HM1 and the isolation material 135 are made of different oxides to provide sufficient etching selectivity.

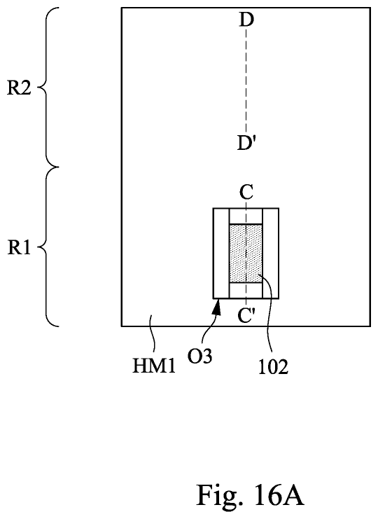

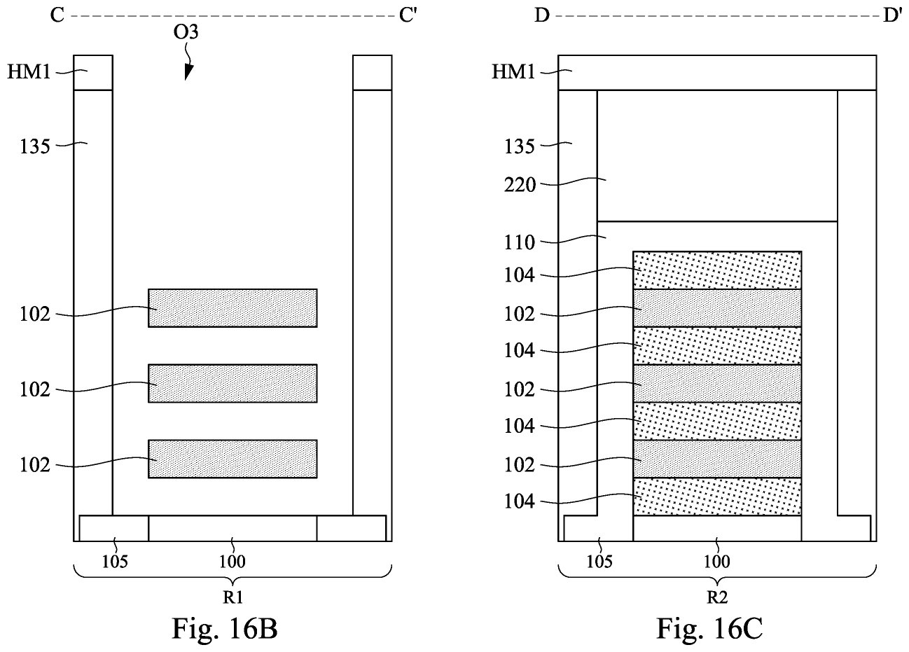

Reference is made to FIGS. 16A, 16B, and 16C, in which FIG. 16A is a top view, and FIGS. 16B and 16C are cross-sectional views along lines C-C′ and D-D′ of FIG. 16A, respectively. The dummy gate structure 120 is removed to form a gate trench. Then, portions of the semiconductor layers 104 within the first region R1 are removed through the gate trench, such that semiconductor layers 102 are suspended over the buffer layer 100. In some embodiments, the portions of the semiconductor layers 104 within the first region R1 may act as sacrificial layers, and the remaining portions of the semiconductor layers 102 within the first region R1 may act as channel layers of the first transistor TR1.

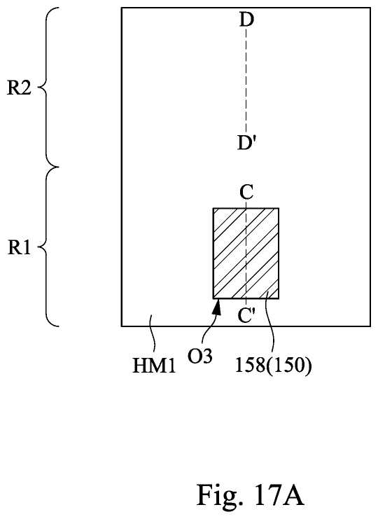

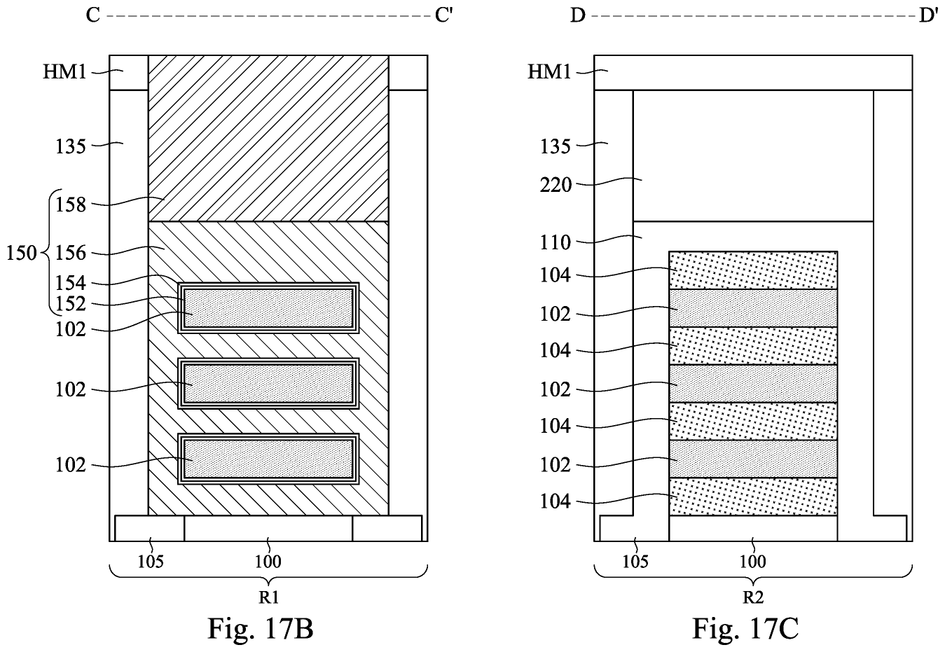

Reference is made to FIGS. 17A, 17B, and 17C, in which FIG. 17A is a top view, and FIGS. 17B and 17C are cross-sectional views along lines C-C′ and D-D′ of FIG. 17A, respectively. A gate structure 150 is formed wrapping around each of the semiconductor layers 102 within the first region R1. In some embodiments, the gate structure 150 may include an interfacial layer 152, a gate dielectric layer 154 over the interfacial layer 152, a work function metal layer 156 over the gate dielectric layer 154, and a gate fill metal 158 over the work function metal layer 156. In some embodiments, the gate structure 150 can also be referred to as metal gate structure.

In some embodiments, the interfacial layer 152 may be made of oxide, such as aluminum oxide (Al₂O₃), silicon oxide (SiO₂), or the like. In some embodiments, the gate dielectric layer 154 includes high-k dielectric. Examples of high-k dielectric material include HfO₂, HfSiO, HfSiON, HfTaO, HfTiO, HfZrO, zirconium oxide, aluminum oxide, titanium oxide, hafnium dioxide-alumina (HfO₂—Al₂O₃) alloy, other suitable high-k dielectric materials, and/or combinations thereof.

The work function metal layer 156 may be an N-type or P-type work function layer. Exemplary P-type work function metals include TiN, TaN, Ru, Mo, Al, ZrSi₂, MoSi₂, TaSi₂, NiSi₂, WN, other suitable P-type work function materials, or combinations thereof. Exemplary N-type work function metals include Ti, Ag, TaAl, TaAlC, TiAlN, TaC, TaCN, TaSiN, Mn, Zr, other suitable N-type work function materials, or combinations thereof. The work function layer may include a plurality of layers. The gate fill metal 158 may include tungsten (W), aluminum (Al), copper (Cu), or another suitable conductive material(s).

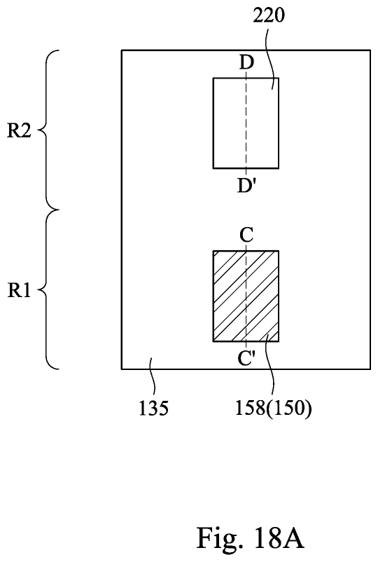

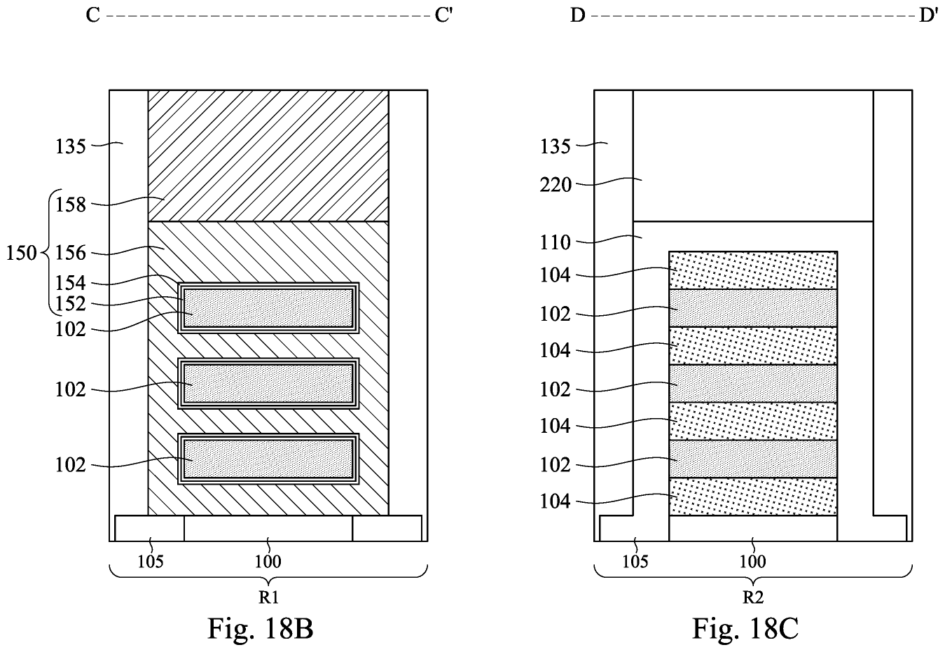

Reference is made to FIGS. 18A, 18B, and 18C, in which FIG. 18A is a top view, and FIGS. 18B and 18C are cross-sectional views along lines C-C′ and D-D′ of FIG. 18A, respectively. The patterned hard mask HM1 is removed. In some embodiments, the patterned hard mask HM1 may be removed using suitable etching process, such as dry etch or wet etch.

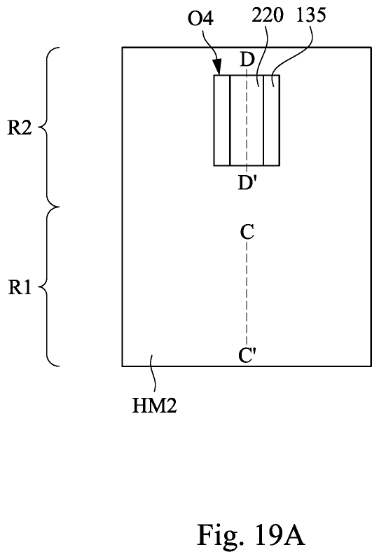

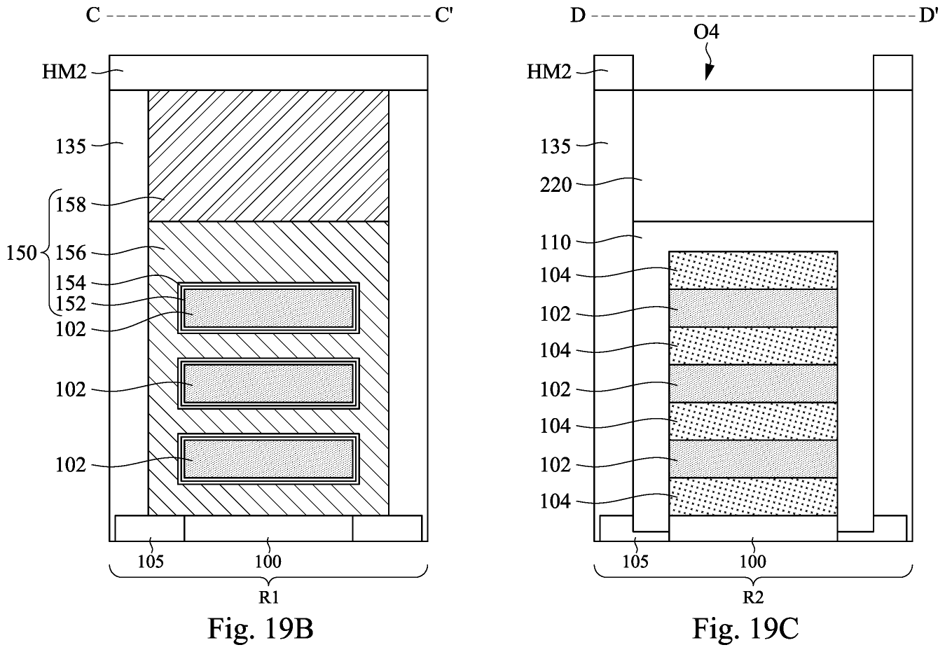

Reference is made to FIGS. 19A, 19B, and 19C, in which FIG. 19A is a top view, and FIGS. 19B and 19C are cross-sectional views along lines C-C′ and D-D′ of FIG. 19A, respectively. A patterned hard mask HM2 is formed over the isolation material 135 and covering the gate structure 150, and the patterned hard mask HM2 may include an opening O4 exposing the dummy gate structure 220. In some embodiments, the patterned hard mask HM2 may be made of suitable dielectric material, such as SiON, or other suitable dielectric material. In some embodiments, the patterned hard mask HM2 and the isolation material 135 are made of different oxides to provide sufficient etching selectivity.

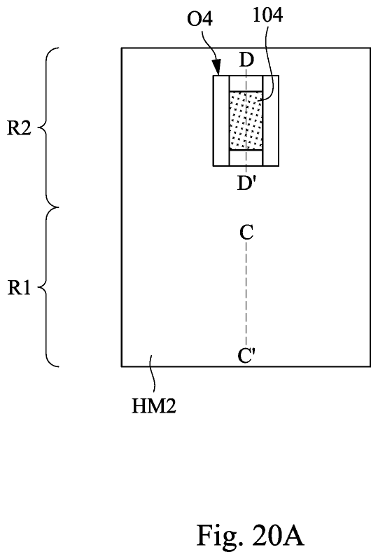

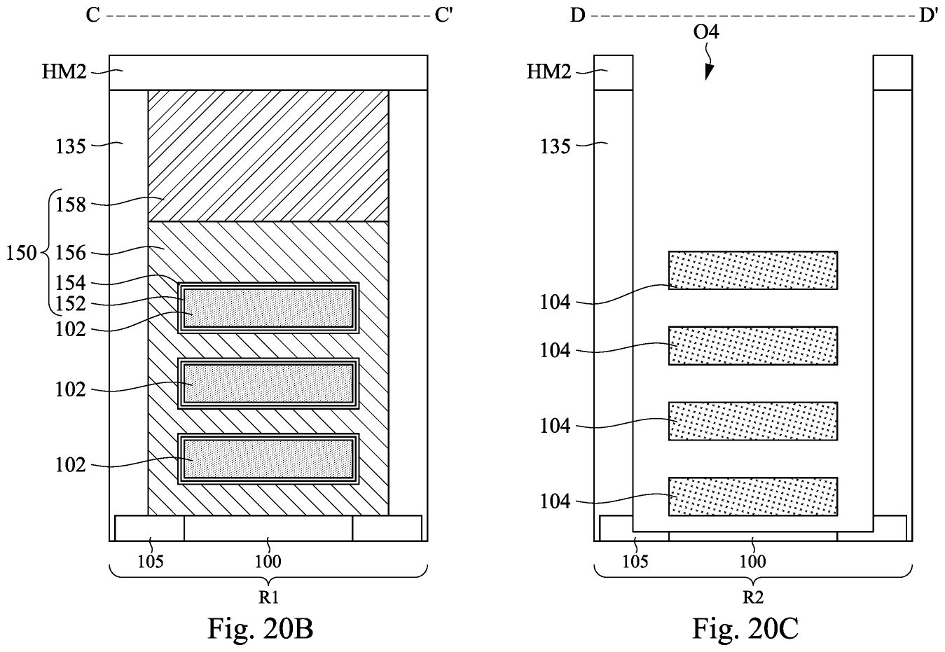

Reference is made to FIGS. 20A, 20B, and 20C, in which FIG. 20A is a top view, and FIGS. 20B and 20C are cross-sectional views along lines C-C′ and D-D′ of FIG. 20A, respectively. The dummy gate structure 220 is removed to form a gate trench. Then, portions of the semiconductor layers 102 within the second region R2 are removed through the gate trench, such that semiconductor layers 104 are suspended over the buffer layer 100. In some embodiments, the portions of the semiconductor layers 102 within the second region R2 may act as sacrificial layers, and the remaining portions of the semiconductor layers 104 within the second region R2 may act as channel layers of the second transistor TR2. In some embodiments, portion of the buffer layer 100 within the second region R2 is slightly removed, such that top surface of the portion of the buffer layer 100 within the second region R2 is lower than portion of the buffer layer 100 within the first region R1.

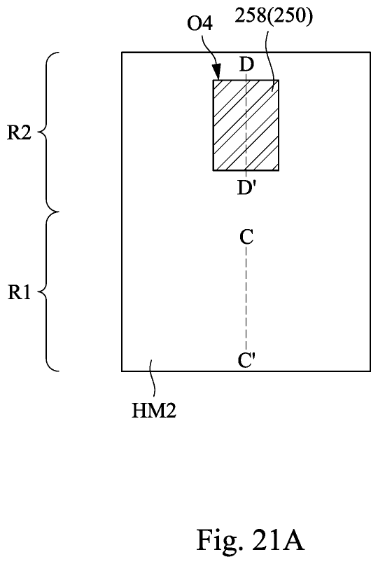

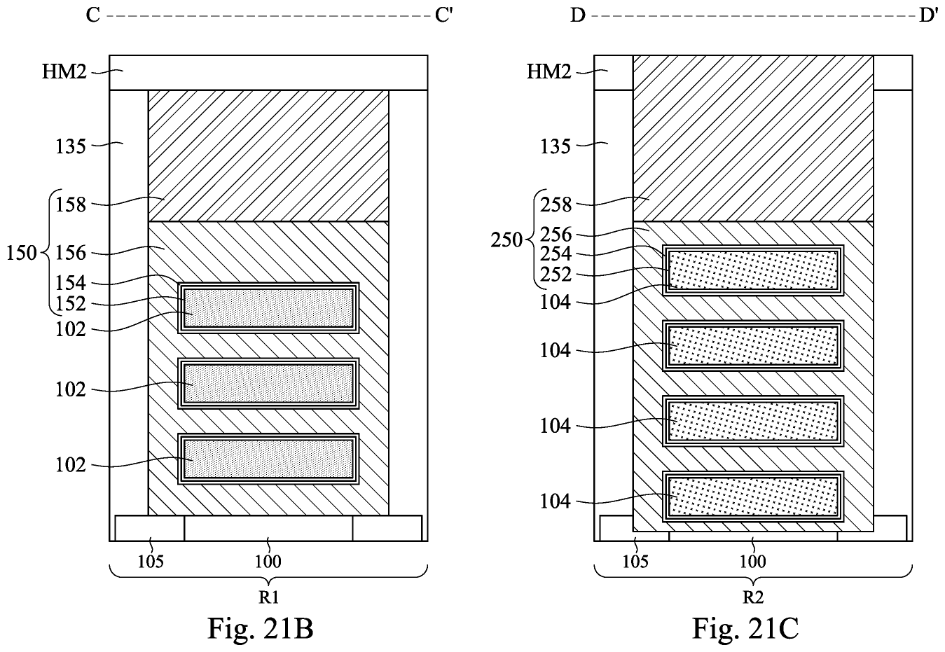

Reference is made to FIGS. 21A, 21B, and 21C, in which FIG. 21A is a top view, and FIGS. 21B and 21C are cross-sectional views along lines C-C′ and D-D′ of FIG. 21A, respectively. A gate structure 250 is formed wrapping around each of the semiconductor layers 104 within the second region R2. In some embodiments, the gate structure 250 may include an interfacial layer 252, a gate dielectric layer 254 over the interfacial layer 252, a work function metal layer 256 over the gate dielectric layer 254, and a gate fill metal 258 over the work function metal layer 256. In some embodiments, the gate structure 250 can also be referred to as metal gate structure. Materials of the interfacial layer 252, the gate dielectric layer 254, the work function metal layer 256, and the gate fill metal 258 may be similar to those described with respect to the interfacial layer 152, the gate dielectric layer 154, the work function metal layer 156, and the gate fill metal 158, and thus relevant details will not be repeated for brevity.

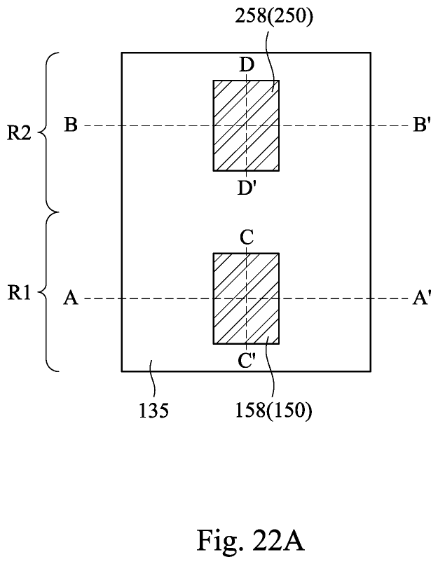

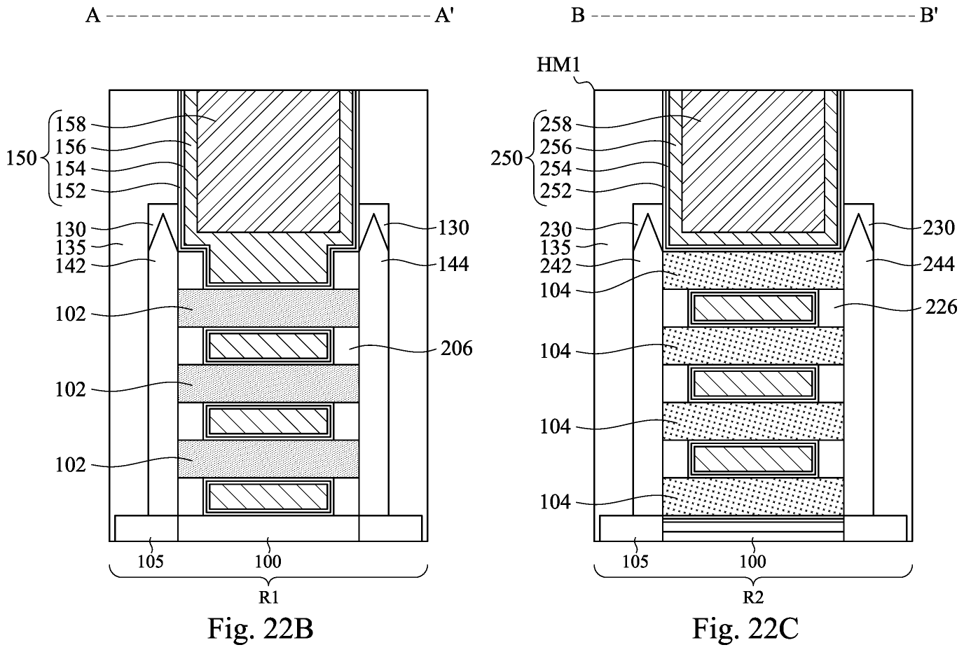

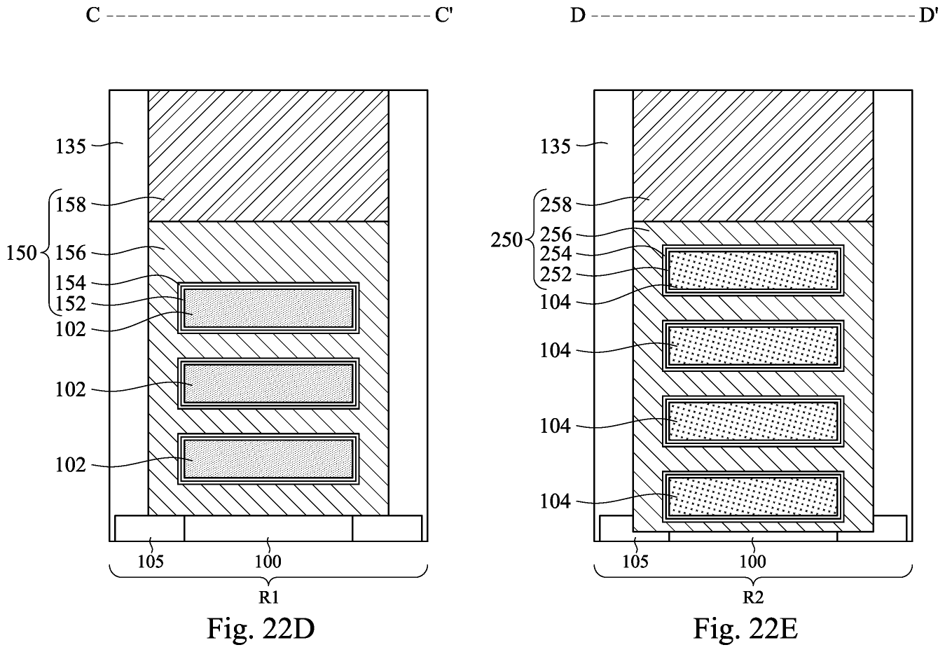

Reference is made to FIGS. 22A, 22B, 22C, 22D, and 22E in which FIG. 22A is a top view, and FIGS. 22B, 22C, 22D, and 22E are cross-sectional views along lines A-A′, B-B′, C-C′, and D-D′ of FIG. 22A, respectively. The patterned hard mask HM2 is removed. In some embodiments, the patterned hard mask HM2 may be removed using suitable etching process, such as dry etch or wet etch. Accordingly, the semiconductor layers 102, the gate structure 150, and the source/drain epitaxy structures 142 and 144 may collectively serve as the transistor TR1 as discussed in FIG. 1. Similarly, the semiconductor layers 104, the gate structure 250, and the source/drain epitaxy structures 242 and 244 may collectively serve as the transistor TR2 as discussed in FIG. 1.

After the patterned mask HM2 is removed, an interconnect structure may be formed over the structure of FIGS. 22A, 22B, 22C, 22D, and 22E. For example, the interconnect structure may include the gate contacts 180, the source contacts 182, the drain contacts 184, the gate contacts 280, the source contacts 282, the drain contacts 284, the conductive pad 192, the conductive pad 194, and the conductive pad 292 as described in FIGS. 2A to 2E, so as to create a desired electrical connection for the power amplifier PA.

According to the aforementioned embodiments, it can be seen that the present disclosure offers advantages in fabricating integrated circuits. It is understood, however, that other embodiments may offer additional advantages, and not all advantages are necessarily disclosed herein, and that no particular advantage is required for all embodiments. Embodiments of the present disclosure provide an integrated circuit, which includes a first transistor and a second transistor. The first transistor includes ultrathin body channel layers. The ultrathin body channel layers are sufficiently thin to create quantum confinement in each channel layer, which in turn will increase the breakdown voltage of the first transistor. The larger breakdown voltage may allow the first transistor to sustain even larger supply voltage VDD and will further enlarge the output power of the power amplifier.

In some embodiments of the present disclosure, an integrated circuit includes a first transistor and a second transistor. The first transistor includes first semiconductor channel layers, first gate structure wrapping around each of the first semiconductor channel layers, and a first source structure and a first drain structure on opposites sides of the first gate structure. The second transistor includes second semiconductor channel layers, second gate structure wrapping around each of the second semiconductor channel layers, and a second source structure and a second drain structure on opposites sides of the second gate structure. The first source structure of the first transistor is electrically coupled to the second drain structure of the second transistor. A thickness of each of the first semiconductor channel layers is less than a thickness of each of the second semiconductor channel layers, and a bandgap of a nanoscale material of the first semiconductor channel layers is larger than a bandgap of a material of the second semiconductor channel layers.

In some embodiments, the thickness of each of the first semiconductor channel layers is in a range from about 0.5 nm to about 5 nm, and the thickness of each of the second semiconductor channel layers is in a range from about 2 nm to about 50 nm.

In some embodiments, each of the first semiconductor channel layers is a quantum well.

In some embodiments, the power amplifier further includes a power supply terminal electrically coupled to the first drain structure of the first transistor, and wherein the second source structure of the second transistor is grounded.

In some embodiments, the power amplifier further includes an input terminal electrically coupled to the second gate structure of the second transistor, and an output terminal electrically coupled to the first drain structure of the first transistor.

In some embodiments, the first semiconductor channel layers are offset from the second semiconductor channel layers along a vertical direction.

In some embodiments, a material of the first semiconductor channel layers is different from a material of the second semiconductor channel layers.

In some embodiments of the present disclosure, an integrated circuit includes a first transistor and a second transistor. The first transistor includes first semiconductor channel layers, first gate structure wrapping around each of the first semiconductor channel layers, and a first source structure and a first drain structure on opposites sides of the first gate structure. The second transistor includes second semiconductor channel layers, second gate structure wrapping around each of the second semiconductor channel layers, and a second source structure and a second drain structure on opposites sides of the second gate structure. The first source structure of the first transistor is electrically coupled to the second drain structure of the second transistor. Each of the first semiconductor channel layers is a quantum well, and each of the second semiconductor channel layers is not a quantum well.

In some embodiments, a thickness of each of the first semiconductor channel layers is less than a thickness of each of the second semiconductor channel layers.

In some embodiments, the thickness of each of the first semiconductor channel layers is less than about 5 nm, and the thickness of each of the second semiconductor channel layers is greater than about 5 nm.

In some embodiments, a bandgap of a material of the first semiconductor channel layers is larger than a bandgap of a material of the second semiconductor channel layers.

In some embodiments, the power amplifier further includes a power supply terminal electrically coupled to the first drain structure of the first transistor, an input terminal electrically coupled to the second gate structure of the second transistor, and an output terminal electrically coupled to the first drain structure of the first transistor.

In some embodiments, a thickness of each of the first semiconductor channel layers is in a range from about 0.5 nm to about 5 nm, and a thickness of each of the second semiconductor channel layers is in a range from about 2 nm to about 50 nm.

In some embodiments, the first transistor includes a plurality of stacks of the first semiconductor channel layers arranged along a lateral direction.

In some embodiments of the present disclosure, a method for forming an integrated circuit includes forming first and second stacks of alternating first semiconductor layers and second semiconductor layers over first and second regions of a substrate, respectively, wherein a thickness of each of the first semiconductor layers is controlled such that quantum confinement occurs in each of the first semiconductor layers; forming first source and drain structures on opposite sides of the first semiconductor layers of the first stack; forming second source and drain structures on opposite sides of the second semiconductor layers of the second stack; removing first portions of the second semiconductor layers of the first stack, while leaving first portions of the first semiconductor layers of the first stack suspended over the substrate; removing second portions of the first semiconductor layers of the second stack, leaving second portions of the second semiconductor layers the second stack suspended over the substrate; forming a first gate structure wrapping around each of the first portions of the first semiconductor layers of the first stack and a second gate structure wrapping around each of the second portions of the second semiconductor layers of the second stack; and forming an interconnect structure electrically coupling the first source structure and the second drain structure.

In some embodiments, a thickness of each of the second semiconductor layers is greater than the thickness of each of the first semiconductor layers, such that no quantum confinement occurs in the second semiconductor layers.

In some embodiments, a bandgap of a material of the first semiconductor layers is larger than a bandgap of a material of the second semiconductor layers.

In some embodiments, the first semiconductor layers and the second semiconductor layers are made of silicon germanium but with different germanium concentrations.

In some embodiments, the method further includes forming a first dummy gate structure and a second dummy gate structure over the first region and the second region of the substrate, respectively; removing the first dummy gate structure to form a first gate trench, wherein removing the first portions of the second semiconductor layers is performed in the first gate trench; and removing the second dummy gate structure to form a second gate trench, wherein removing the second portions of the first semiconductor layers is performed in the second gate trench.

In some embodiments, the interconnect structure further includes a power supply terminal electrically coupled to the first drain structure, an input terminal electrically coupled to the second gate structure, and an output terminal electrically coupled to the first drain structure.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. An integrated circuit, comprising:
a first transistor, comprising:
first semiconductor channel layers;
first gate structure wrapping around each of the first semiconductor channel layers; and
a first source structure and a first drain structure on opposites sides of the first gate structure; and
a second transistor, comprising:
second semiconductor channel layers, wherein a thickness of each of the first semiconductor channel layers is less than a thickness of each of the second semiconductor channel layers, and a bandgap of a nanoscale material of the first semiconductor channel layers is larger than a bandgap of a material of the second semiconductor channel layers;
second gate structure wrapping around each of the second semiconductor channel layers; and
a second source structure and a second drain structure on opposite sides of the second gate structure, wherein the first source structure of the first transistor is electrically coupled to the second drain structure of the second transistor.

2. The integrated circuit of claim 1, wherein the thickness of each of the first semiconductor channel layers is in a range from about 0.5 nm to about 5 nm, and the thickness of each of the second semiconductor channel layers is in a range from about 2 nm to about 50 nm.

3. The integrated circuit of claim 1, wherein each of the first semiconductor channel layers is a quantum well.

4. The integrated circuit of claim 1, further comprising a power supply terminal electrically coupled to the first drain structure of the first transistor, and wherein the second source structure of the second transistor is grounded.

5. The integrated circuit of claim 4, further comprising:
an input terminal electrically coupled to the second gate structure of the second transistor; and
an output terminal electrically coupled to the first drain structure of the first transistor.

6. The integrated circuit of claim 1, wherein the first semiconductor channel layers are offset from the second semiconductor channel layers along a vertical direction.

7. The integrated circuit of claim 1, wherein a material of the first semiconductor channel layers is different from a material of the second semiconductor channel layers.

8. An integrated circuit, comprising:
a first transistor, comprising:
first semiconductor channel layers, wherein each of the first semiconductor channel layers is a quantum well;
first gate structure wrapping around each of the first semiconductor channel layers; and
a first source structure and a first drain structure on opposites sides of the first gate structure; and
a second transistor, comprising:
second semiconductor channel layers, wherein each of the second semiconductor channel layers is not a quantum well;
second gate structure wrapping around each of the second semiconductor channel layers; and
a second source structure and a second drain structure on opposites sides of the second gate structure, wherein the first source structure of the first transistor is electrically coupled to the second drain structure of the second transistor.

9. The integrated circuit of claim 8, wherein a thickness of each of the first semiconductor channel layers is less than a thickness of each of the second semiconductor channel layers.

10. The integrated circuit of claim 9, wherein the thickness of each of the first semiconductor channel layers is less than about 5 nm, and the thickness of each of the second semiconductor channel layers is greater than about 5 nm.

11. The integrated circuit of claim 8, wherein a bandgap of a material of the first semiconductor channel layers is larger than a bandgap of a material of the second semiconductor channel layers.

12. The integrated circuit of claim 8, further comprising:
a power supply terminal electrically coupled to the first drain structure of the first transistor;
an input terminal electrically coupled to the second gate structure of the second transistor; and
an output terminal electrically coupled to the first drain structure of the first transistor.

13. The integrated circuit of claim 8, wherein a thickness of each of the first semiconductor channel layers is in a range from about 0.5 nm to about 5 nm, and a thickness of each of the second semiconductor channel layers is in a range from about 2 nm to about 50 nm.

14. The integrated circuit of claim 8, wherein the first transistor comprises a plurality of stacks of the first semiconductor channel layers arranged along a lateral direction.

15. A method for forming an integrated circuit, comprising:
forming first and second stacks of alternating first semiconductor layers and second semiconductor layers over first and second regions of a substrate, respectively, wherein a thickness of each of the first semiconductor layers is controlled such that quantum confinement occurs in each of the first semiconductor layers;
forming first source and drain structures on opposite sides of the first semiconductor layers of the first stack;
forming second source and drain structures on opposite sides of the second semiconductor layers of the second stack;
removing first portions of the second semiconductor layers of the first stack, while leaving first portions of the first semiconductor layers of the first stack suspended over the substrate;
removing second portions of the first semiconductor layers of the second stack, leaving second portions of the second semiconductor layers the second stack suspended over the substrate;
forming a first gate structure wrapping around each of the first portions of the first semiconductor layers of the first stack and a second gate structure wrapping around each of the second portions of the second semiconductor layers of the second stack; and
forming an interconnect structure electrically coupling the first source structure and the second drain structure.

16. The method of claim 15, wherein a thickness of each of the second semiconductor layers is greater than the thickness of each of the first semiconductor layers, such that no quantum confinement occurs in the second semiconductor layers.

17. The method of claim 16, wherein a bandgap of a material of the first semiconductor layers is larger than a bandgap of a material of the second semiconductor layers.

18. The method of claim 15, wherein the first semiconductor layers and the second semiconductor layers are made of silicon germanium but with different germanium concentrations.

19. The method of claim 15, further comprising:
forming a first dummy gate structure and a second dummy gate structure over the first region and the second region of the substrate, respectively;
removing the first dummy gate structure to form a first gate trench, wherein removing the first portions of the second semiconductor layers is performed in the first gate trench; and
removing the second dummy gate structure to form a second gate trench, wherein removing the second portions of the first semiconductor layers is performed in the second gate trench.

20. The method of claim 15, wherein the interconnect structure further comprises:
a power supply terminal electrically coupled to the first drain structure;
an input terminal electrically coupled to the second gate structure; and
an output terminal electrically coupled to the first drain structure.
